(19) United States
(12) Patent Application Publication
(10) Pub. No.: US 2010/0081085 A1
(43) Pub. Date: Apr. 1, 2010

(54) Polymer and Resist Composition Comprising the Same

(75) Inventors: Nobuo ANDO, Toyonaka-shi (JP); Kazuhiko HASHIMOTO, Toyonaka-shi (JP)

Correspondence Address: HOGAN & HARTSON L.L.P., 1999 AVENUE OF THE STARS, SUITE 1400, LOS ANGELES, CA, 90067, US

(73) Assignee: SUMITOMO CHEMICAL COMPANY, LIMITED, Tokyo (JP)

(21) Appl. No.: 12/563,808

(22) Filed: Sep. 21, 2009

(30) Foreign Application Priority Data
Sep. 29, 2008 (JP) 2008-250342

(51) Int. Cl. G03F 7/004; C08F 12/24

(52) U.S. Cl. 430/270.1; 526/313

(57) ABSTRACT

A polymer comprising a structural unit represented by the formula (I):

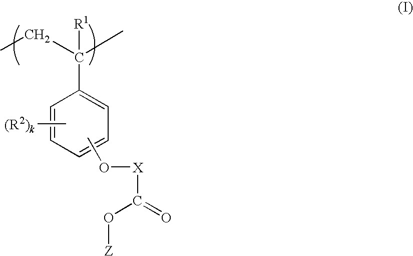

wherein R¹ represents a hydrogen atom or a methyl group, R² is independently in each occurrence a linear or branched chain C1-C6 alkyl group, k represents an integer of 0 to 4, X represents a linear or branched chain C1-C6 alkylene group, Z represents a 2-adamantyl group which may have one or more substituents, and a structural unit represented by the formula (II):

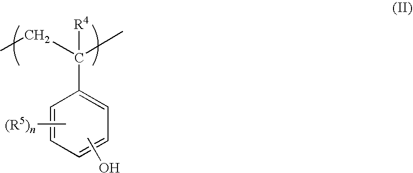

wherein R⁴ represents a hydrogen atom or a methyl group, R⁵ is independently in each occurrence a linear or branched chain C1-C6 alkyl group and n represents an integer of 0 to 4.

This nonprovisional application claims priority under 35 U.S.C. §119(a) on Patent Application No 2008-250342 filed in JAPAN on Sep. 29, 2008, the entire contents of which are hereby incorporated by reference.

### FIELD OF THE INVENTION

The present invention relates to a polymer and a resist composition comprising the same.

### BACKGROUND OF THE INVENTION

A resist composition used for semiconductor microfabrication employing a lithography process contains an acid generator comprising a compound generating an acid by irradiation.

In semiconductor microfabrication, it is desirable to form patterns having high sensitivity and high resolution and good pattern profile such as shape of the pattern, and it is expected for a chemically amplified resist composition to give such patterns.

JP 2005-274877 A discloses a resist composition comprising a resin which is insoluble or poorly soluble in an alkali aqueous solution but becomes soluble in an alkali aqueous solution by the action of an acid and which comprises a structural unit derived from hydroxystyrene and a structural unit derived from an acrylate monomer or a methacrylate monomer.

### SUMMARY OF THE INVENTION

The present invention is to provide a polymer and a resist composition containing the same.

The present invention relates to the followings:

<1> A polymer comprising a structural unit represented by the formula (I):

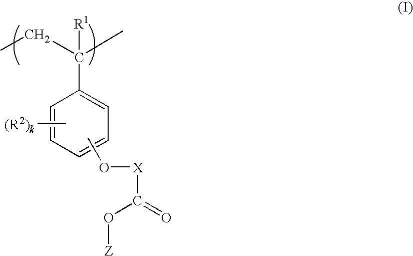

wherein R¹ represents a hydrogen atom ox a methyl group, R² is independently in each occurrence a linear or branched chain C1-C6 alkyl group, k represents an integer of 0 to 4, X represents a linear or branched chain C1-C6 alkylene group, Z represents a 2-adamantyl group which may have one or more substituents selected from the group consisting of a linear chain C1-C6 alkyl group, a branched chain C3-C6 alkyl group and a hydroxyl group, and in which a methylene group may be replaced by a carbonyl group, and a structural unit represented by the formula (II):

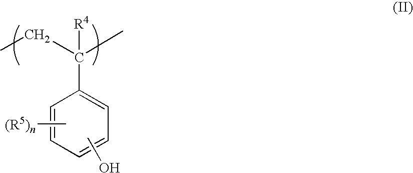

wherein R⁴ represents a hydrogen atom or a methyl group, R⁵ is independently in each occurrence a linear or branched chain C1-C6 alkyl group and n represents an integer of 0 to 4;

<2> A resist composition comprising the polymer according to <1> and an acid generator;

<3> The resist composition according to <2>, wherein the acid generator is a salt represented by the formula (V):

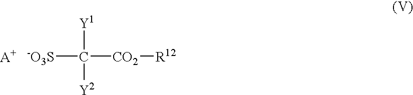

wherein A⁺ represents an organic counter ion, Y¹ and Y² each independently represent a fluorine atom or a C1-C6 perfluoroalkyl group, R¹² represents a C1-C30 hydrocarbon group which may have one or more substituents selected from the group consisting of a C1-C6 alkoxy group, a C1-C4 perfluoroalkyl group, a C1-C6 hydroxyalkyl group, a hydroxyl group and a cyano group, and in which one or more —CH₂— may be replace by —CO— or —O—.

### DESCRIPTION OF PREFERRED EMBODIMENTS

The present polymer comprises a structural unit represented by the formula (I):

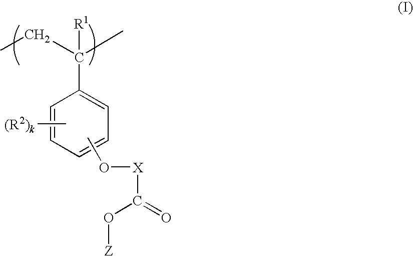

(hereinafter, simply referred to as the structural unit (I)) and a structural unit represented by the formula (II):

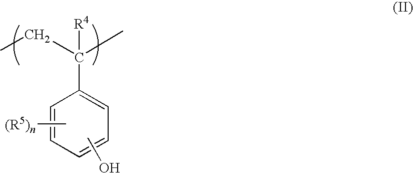

(hereinafter, simply referred to as the structural unit (II)).

In the formula (I), R¹ represents a hydrogen atom or a methyl group, R² is independently in each occurrence a linear or branched chain C1-C6 alkyl group. Examples of the linear or branched chain C1-C6 alkyl group include a methyl group, an ethyl group, a propyl group, an isopropyl group, a butyl group, an isobutyl group, a sec-butyl group, a pentyl group, an isopentyl group, a neopentyl group and a hexyl group, and a methyl group is preferable. In the formula (I), k represents an integer of 0 to 4, and k is preferably 0 or 1, and more preferably 0.

In the formula (I), X represents a linear or branched chain C1-C6 alkylene group. Examples of the linear or branched chain C1-C6 alkylene group include a methylene group, an ethylene group, a trimethylene group, a tetramethylene group, a 2-methylbutylene group, a pentramethylene group and a hexamethylene group, and a methylene group and an ethylene group are preferable.

Z represents a 2-adamantyl group which may have one or more substituents selected from the group consisting of a linear chain C1-C6 alkyl group, a branched chain C3-C6 alkyl group and a hydroxyl group, and in which a methylene group may be replaced by a carbonyl group. Examples of the linear chain C1-C6 alkyl group include a methyl group, an ethyl group, a propyl group, a butyl group, a pentyl group and a hexyl group, and a methyl group and an ethyl group are preferable. Examples of the branched chain C3-C6 alkyl group include an isopropyl group, an isobutyl group, a sec-butyl group, an isopentyl group and a neopentyl group, and an isopropyl group is preferable. Z is preferably a 2-adamantyl group which has the linear or branched chain C1-C6 alkyl group at 2-position and which may have one or more a linear or branched chain C1-C6 alkyl group, and more preferably a 2-methyl-2-adamantyl group or a 2-ethyl-2-adamantyl group which may have one or more substituents selected from the group consisting of a linear chain C1-C6 alkyl group and a branched chain C3-C6 alkyl group, and especially preferably a 2-methyl-2-adamantyl group or a 2-ethyl-2-adamantyl group.

The structural unit represented by the formula (I-1):

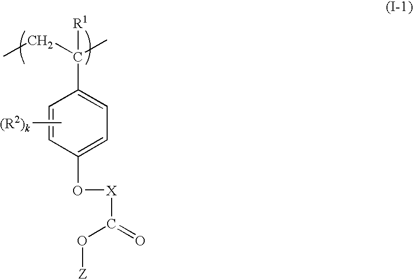

wherein R¹, R², X, Z and k are the same meanings as defined above, is preferable.

Examples of the structural unit (I) include the followings.

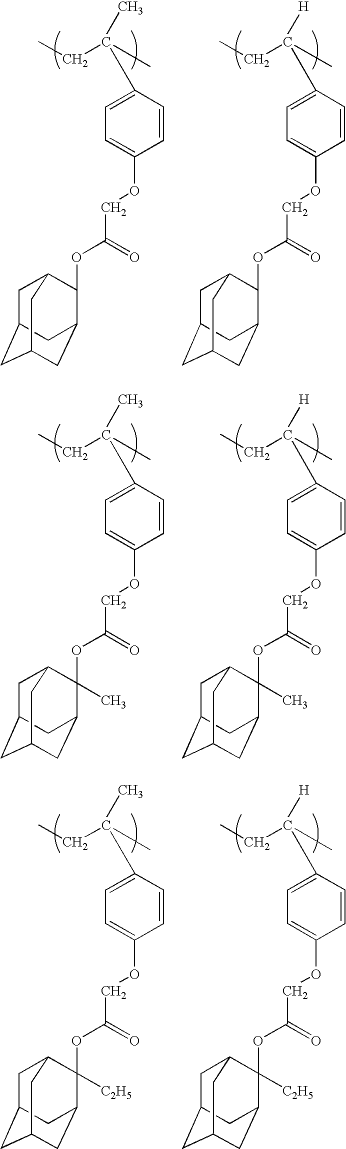

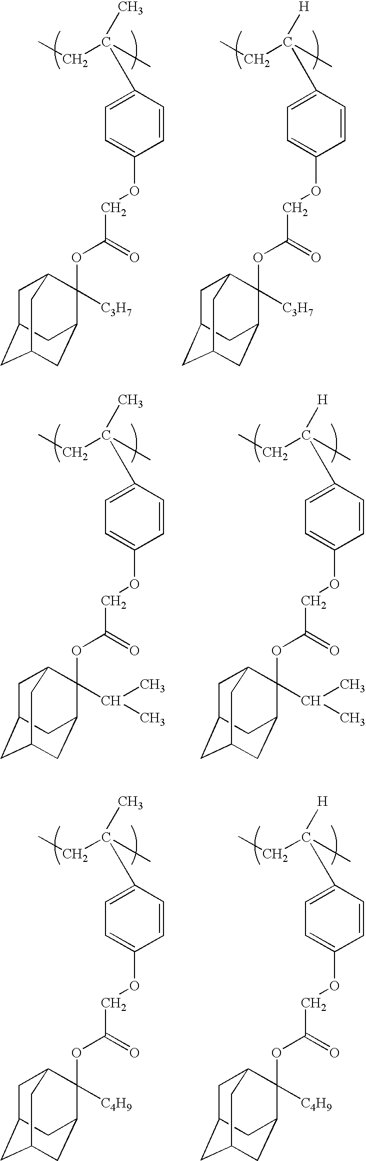

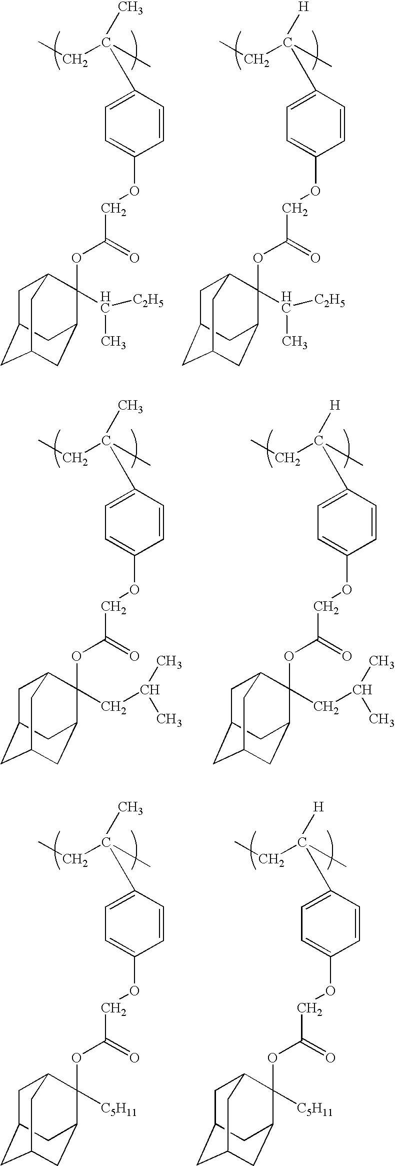

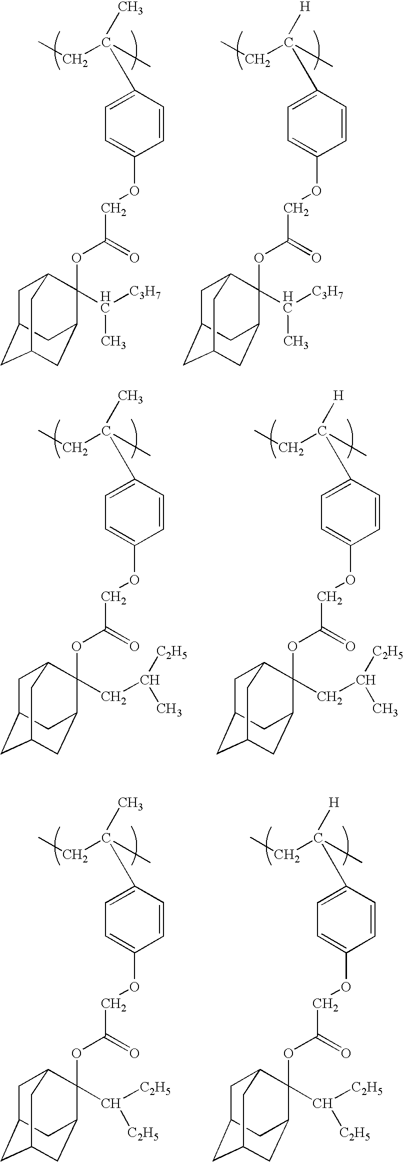

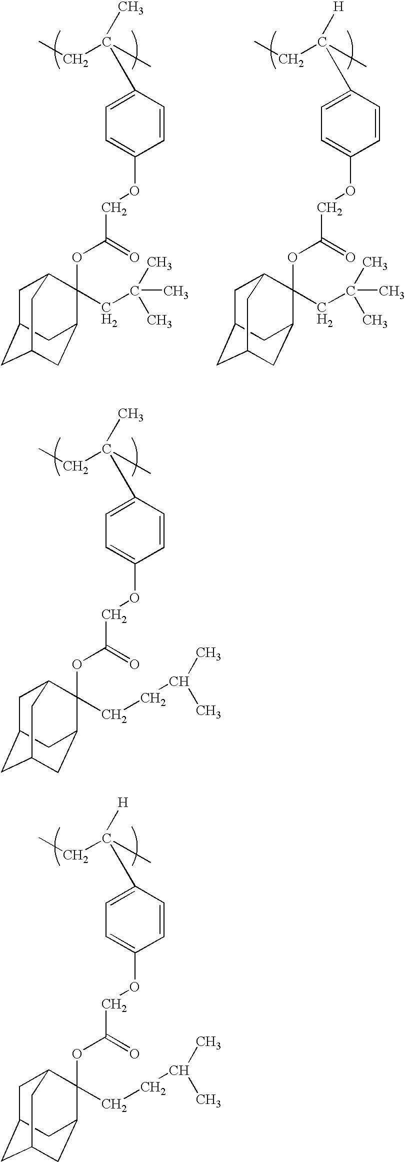

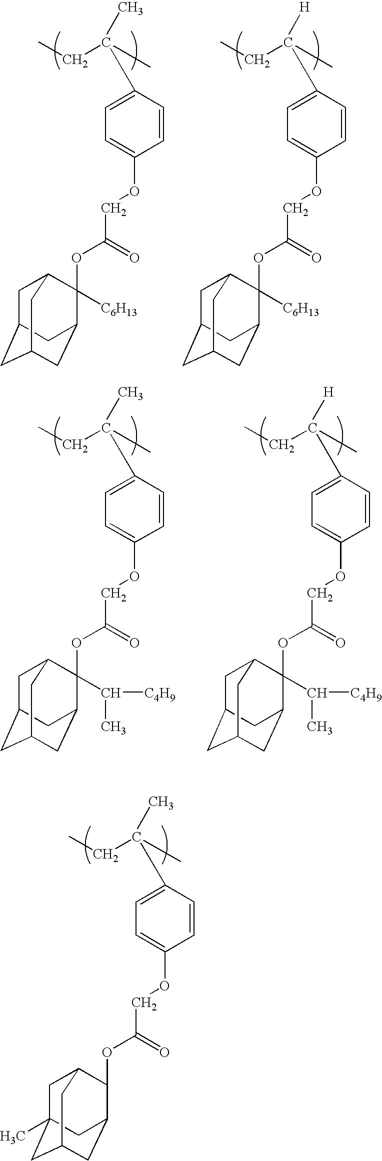

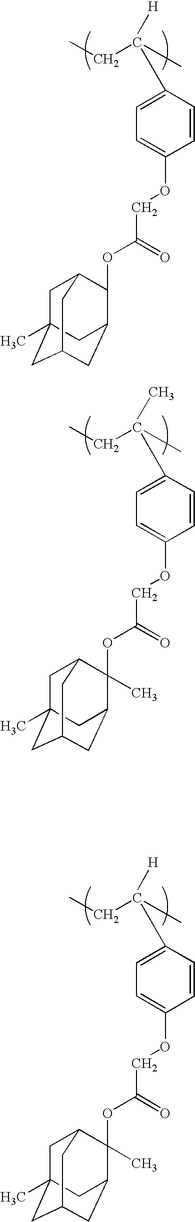

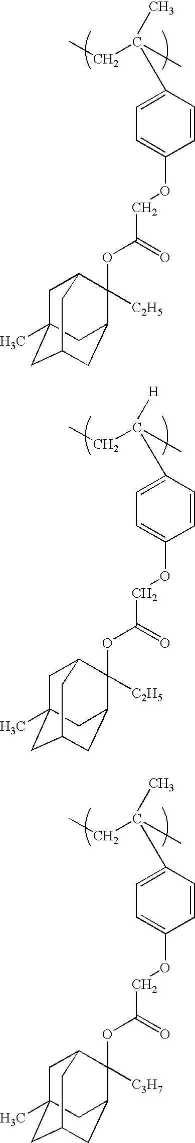

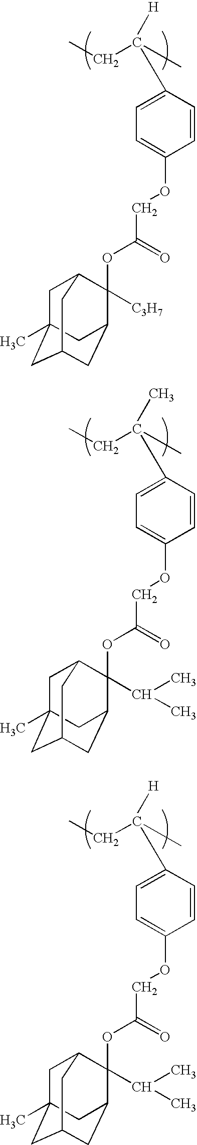

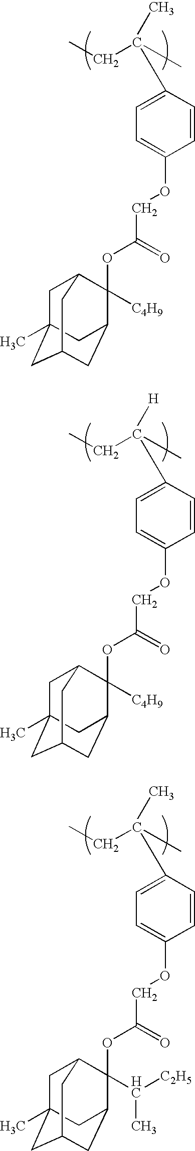

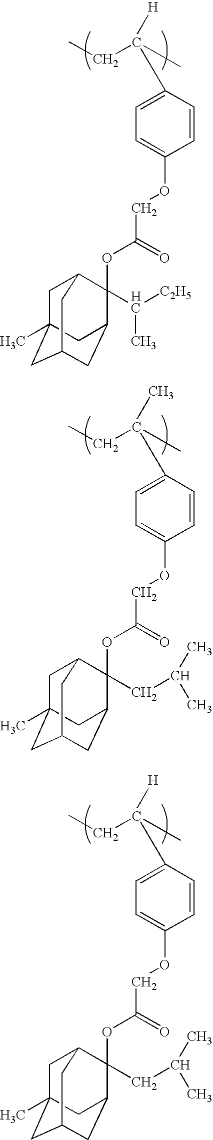

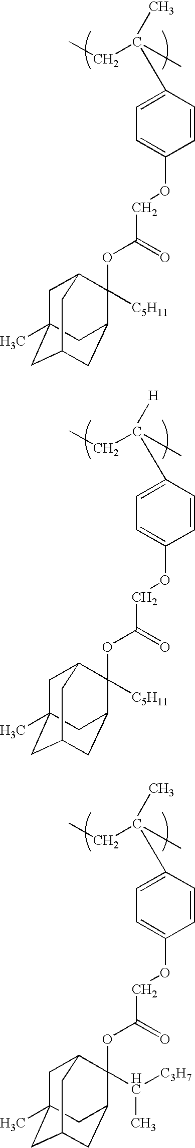

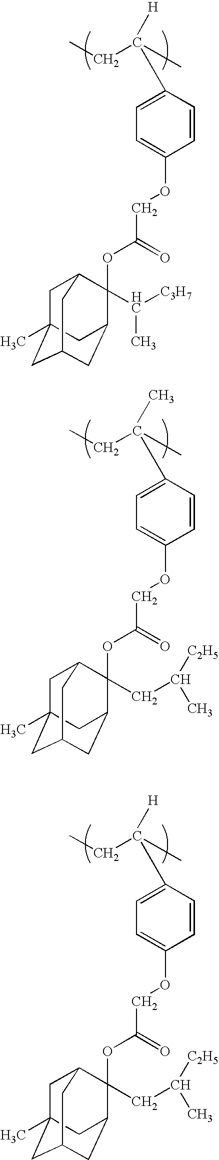

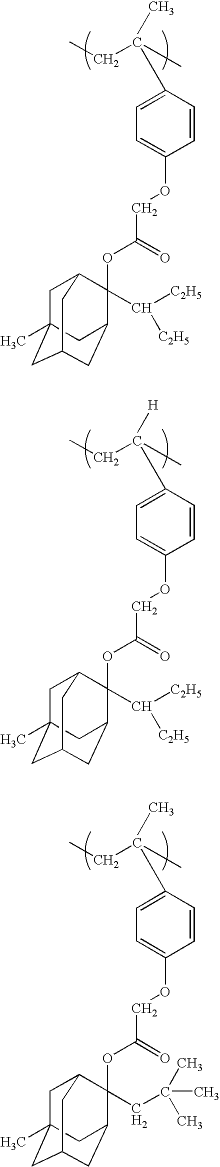

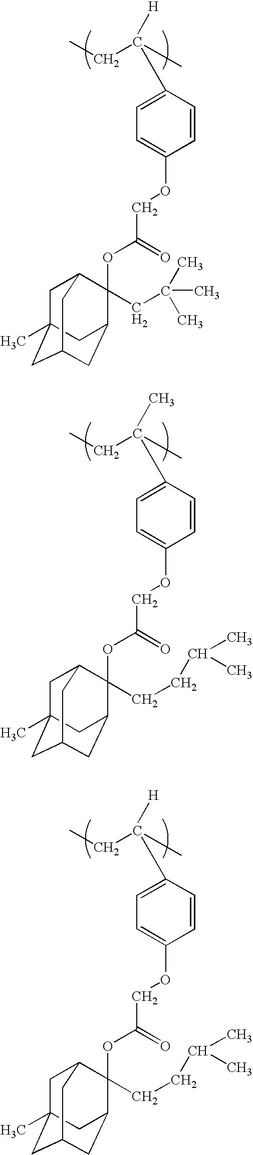

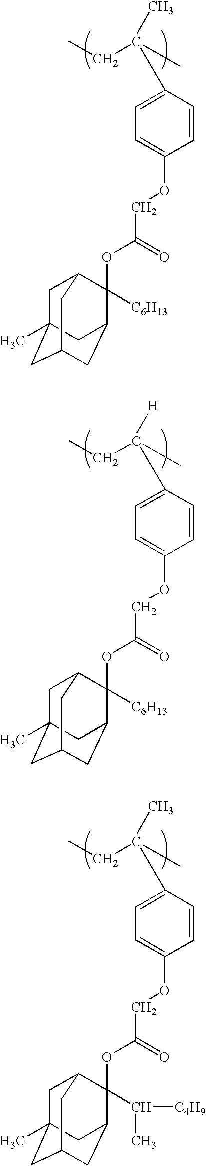

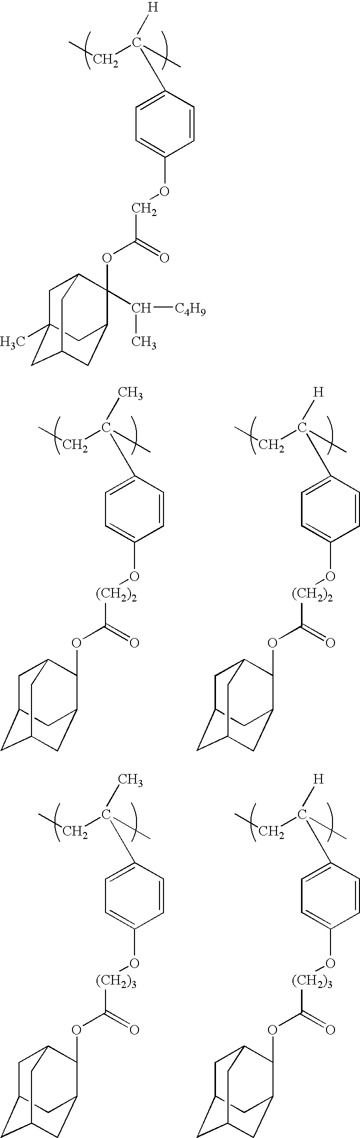

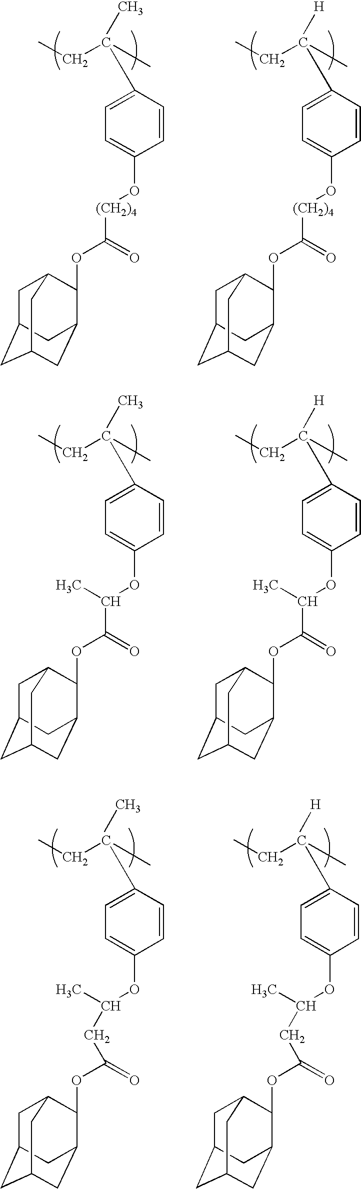

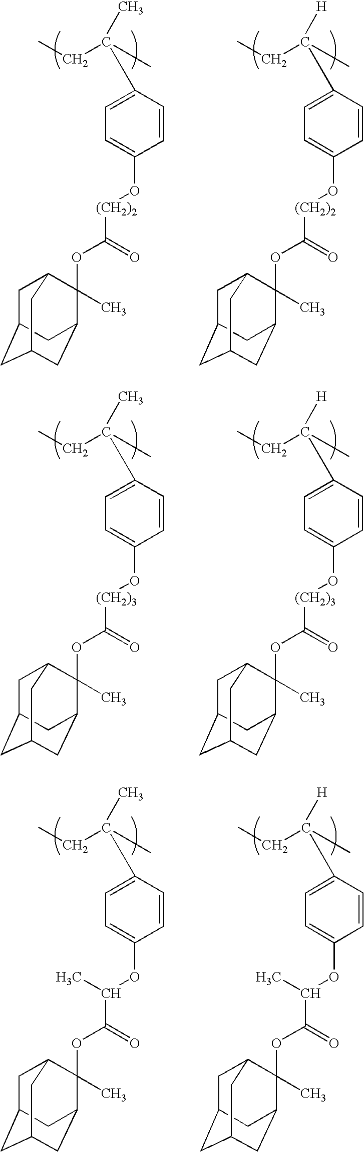

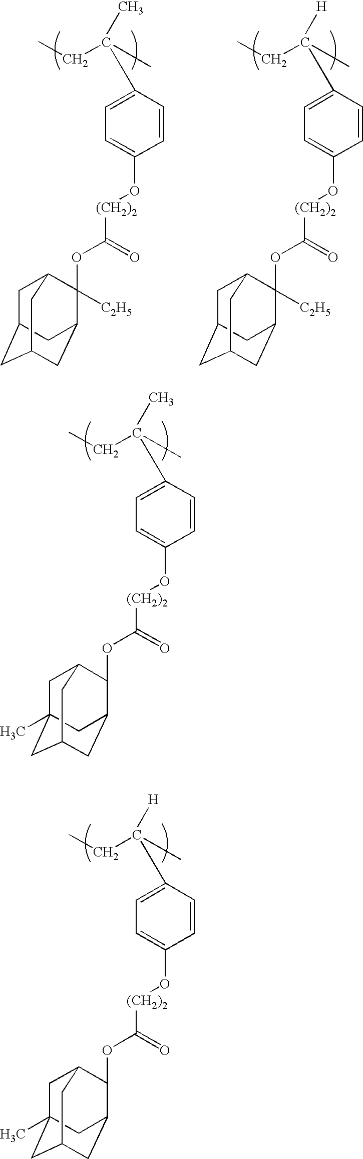

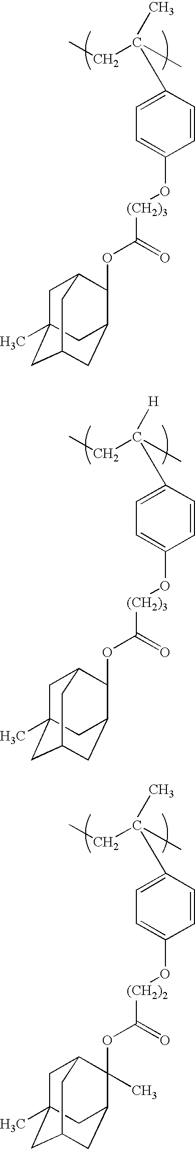

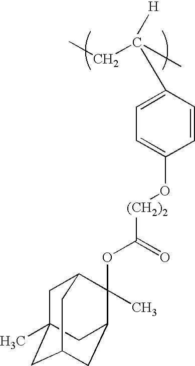

Among them, the structural unit derived from 4-(2-alkyl-2-adamnantyloxycarbonylmethoxy)styrene and the structural unit derived from 4-(2-alkyl-2-adamantyloxycarbonylmethoxy)-α-styrene are preferable.

In the formula (II), R⁴represents a hydrogen atom or a methyl group, R⁵ is independently in each occurrence a linear or branched chain C1-C6 alkyl group. Examples of the linear or branched chain C1-C6 alkyl group include the same as described above, and a methyl group is preferable. In the formula (II), n represents an integer of 0 to 4, and n is preferably 0 or 1, and more preferably 0.

The structural unit represented by the formula (II-1):

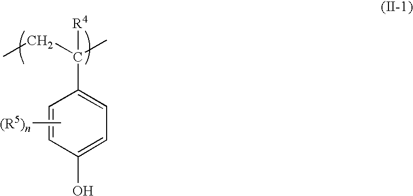

wherein R⁴, R⁵ and n are the same meanings as defined above, is preferable.

Examples of the structural unit (II) include the followings.

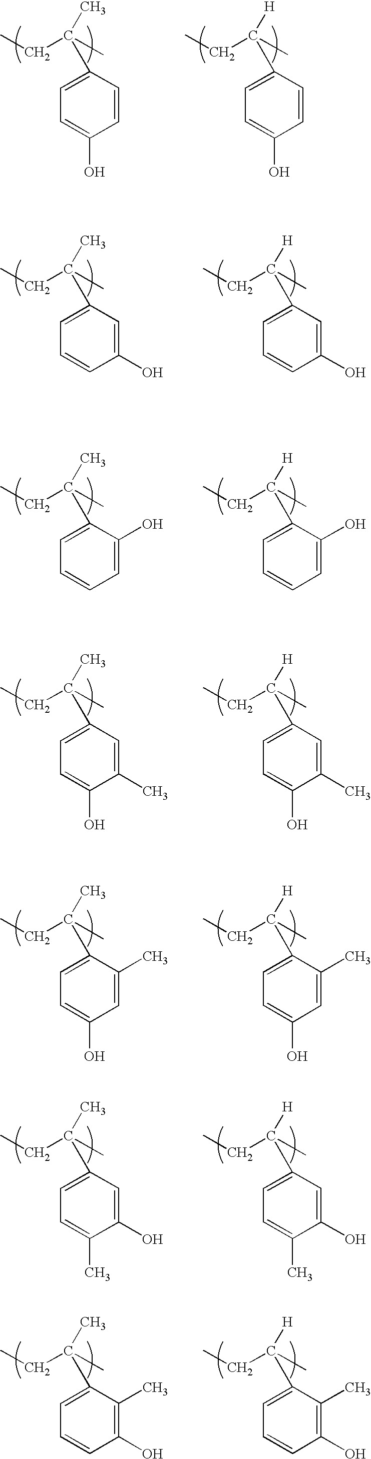

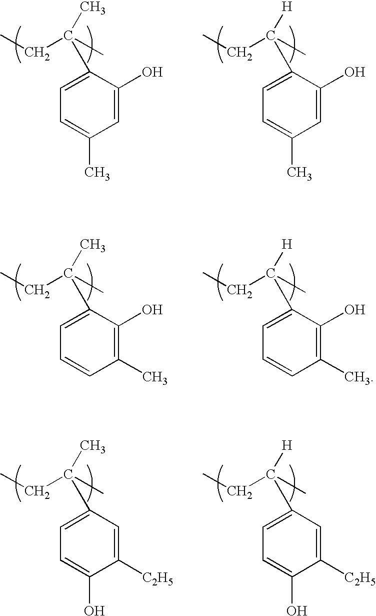

Among them, the structural unit derived from 4-hydroxystyrene and the structural unit derived from 4-hydroxy-α-styrene are preferable.

The polymer of the present invention may contain two or more kinds of the structural unit (I) and may contain two or more kinds of the structural unit (II).

The content of the structural unit (I) in the present polymer is usually 10 to 90 mol % and preferably 20 to 60 mol % based on the total molar of all of the structural units. The content of the structural unit (II) in the present polymer is usually 10 to 90 mol % and preferably 40 to 80 mol % based on the total molar of all of the structural units from the viewpoint of resolution and pattern profile.

The weight-average molecular weight of the present polymer is usually 1,000 to 500,000 and preferably 4,000 to 50,000.

The polymer of the present invention can be produced by reacting a resin comprising a structural unit derived from a hydroxystyrene or a hydroxyl-α-styrene with a halogenated alkanoic acid adamantyl ester compound in the presence of a base. The content of the structural unit (I) in the present polymer can be adjusted by adjusting the used amount of the halogenated alkanoic acid adamantyl ester compound.

The reaction is usually carried out in a solvent. Examples of the solvent include an aromatic hydrocarbon such as toluene; an ether such as 1,4-dioxane and tetrahydrofuran; a ketone such as acetone and methyl ethyl ketone; an alcohol such as isopropanol; a glycol ether ester such as propylene glycol monomethyl ether acetate; an acyclic ester such as ethyl lactate and butyl acetate; and a cyclic ester such as γ-butyrolactone. These solvents may be used alone and two or more thereof may be mixed to use. The used amount of the solvent is not limited.

As the base, an inorganic base is usually used, and examples of the inorganic base include an alkali metal hydroxide such as sodium hydroxide and potassium hydroxide, and an alkali metal carbonate such as sodium carbonate and potassium carbonate. The used amount of the base is usually 1 to 5 moles per 1 mole of the halogenated alkanoic acid adamantyl ester compound.

The reaction may be conducted in the presence of an alkali metal iodide such as sodium iodide and potassium iodide.

The reaction temperature is usually 0 to 150° C.

The polymer of the present invention is insoluble or poorly soluble in an alkali aqueous solution but becomes soluble in an alkali aqueous solution by the action of an acid.

The present resist composition comprises the polymer of the present invention and an acid generator.

The acid generator is a substance which is decomposed to generate an acid by applying a radiation such as a light, an electron beam or the like on the substance itself or on a resist composition containing the substance. The acid generated from the acid generator acts on the present polymer resulting in dissolving the present polymer in an alkali aqueous solution.

Examples of the acid generator include an onium salt compound, an organo-halogen compound, a sulfone compound, a sulfonate compound, and the like. The onium salt compound is preferable.

Other examples of the acid generator include acid generators described in JP 2003-5374 A1.

Examples of the preferable acid generator include a salt represented by the formula (V):

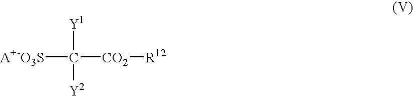

wherein A⁺ represents an organic counter ion, Y¹ and Y² each independently represent a fluorine atom or a C1-C6 perfluoroalkyl group, R¹² represents a C1-C30 hydrocarbon group which may have one or more substituents selected from the group consisting of a C1-C6 alkoxy group, a C1-C4 perfluoroalkyl group, a C1-C6 hydroxyalkyl group, a hydroxyl group and a cyano group, and in which one or more —CH₂— may be replace by —CO— or —O— (hereinafter, simply referred to as Salt (V)),

Examples of the C1-C6 perfluoroalkyl group represented by Y¹ and Y² include a trifluoromethyl group, a pentaftluoroethyl group, a heptafluoropropyl group, a nonafluorobutyl group, an undecafluoropentyl group and a tridecafluorohexyl group, and a trifluoromethyl group is preferable. Y¹ and Y² each independently is preferably a fluorine atom or a trifluoromethyl group, and Y¹ and Y² are more preferably fluorine atoms.

Examples of the C1-C30 hydrocarbon group include a linear or branched chain C1-C30 hydrocarbon group such as a methyl group, an ethyl group, an n-propyl group, an isopropyl group, an n-butyl group, an isobutyl group, a sec-butyl group, a tert-butyl group, an n-pentyl group and an n-hexyl group, and a C3-C30 monocyclic or polycyclic hydrocarbon group such as a hydrocarbon group having a cyclobutane ring, a hydrocarbon group having a cyclopentane ring, a hydrocarbon group having a cyclohexane ring, a hydrocarbon group having a cyclooctane ring, a hydrocarbon group having an adamantane ring, a hydrocarbon group having a benzene ring and a hydrocarbon group having a norbornane ring. The C3-C30 monocyclic or polycyclic hydrocarbon group may have an alicyclic structure or structures and may have an aromatic group or groups. The C3-C30 monocyclic or polycyclic hydrocarbon group may have a carbon-carbon double bond or bonds.

The C1-C30 hydrocarbon group may have one or more substituents selected from the group consisting of a C1-C6 alkoxy group, a C1-C4 perfluoroalkyl group, a C1-C6 hydroxyalkyl group, a hydroxyl group and a cyano group. Examples of the C1-C6 alkoxy group include a methoxy group, an ethoxy group, an n-propoxy group, an isopropoxy group, an n-butoxy group, an isobutoxy group, a sec-butoxy group, a tert-butoxy group, an n-pentyloxy group and an n-hexyloxy group. Examples of the C1-C4 perfluoroalkyl group include a trifluoromethyl group, a pentafluoroethyl group, a heptafluoropropyl group and a nonafluorobutyl group. Examples of the C1-C6 hydroxyalkyl group include a hydroxymethyl group, a 2-hydroxyethyl group, a 3-hydroxypropyl group, a 4-hydroxybutyl group and a 6-hydroxyhexyl group.

Specific examples of the anion part of Salt (V) include the followings.

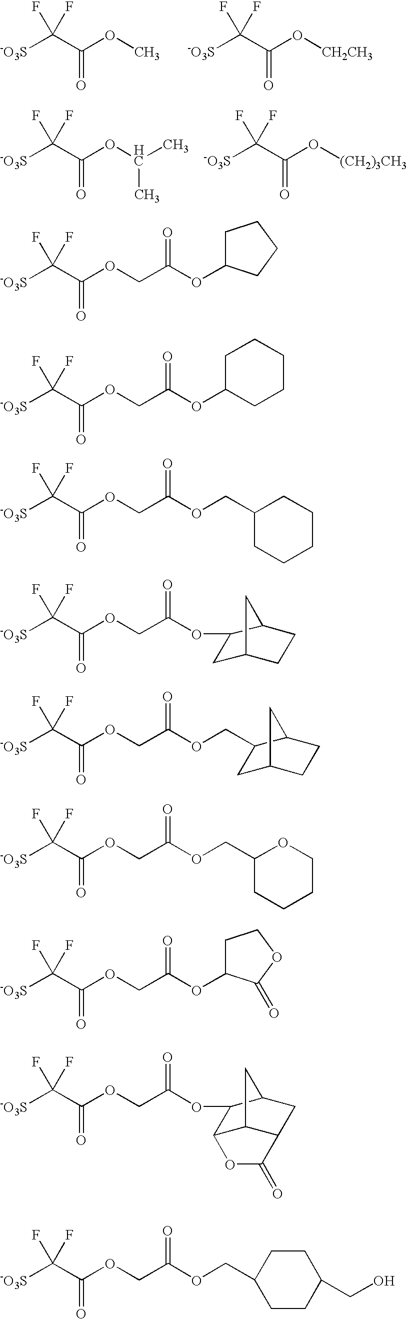

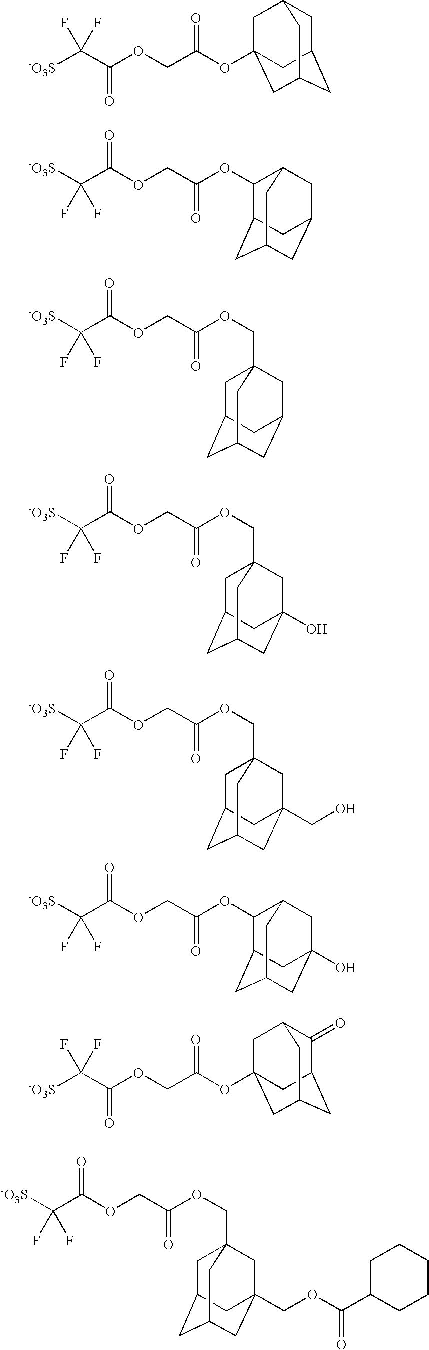

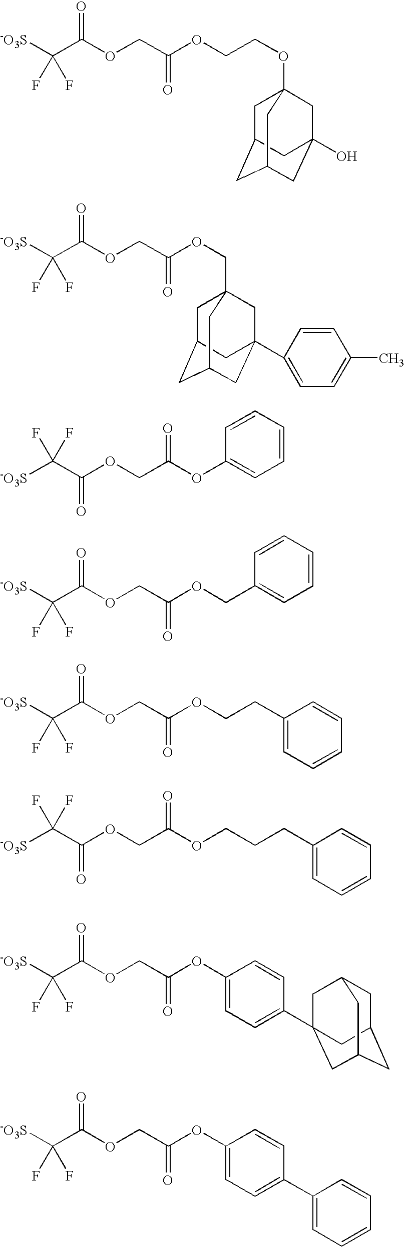

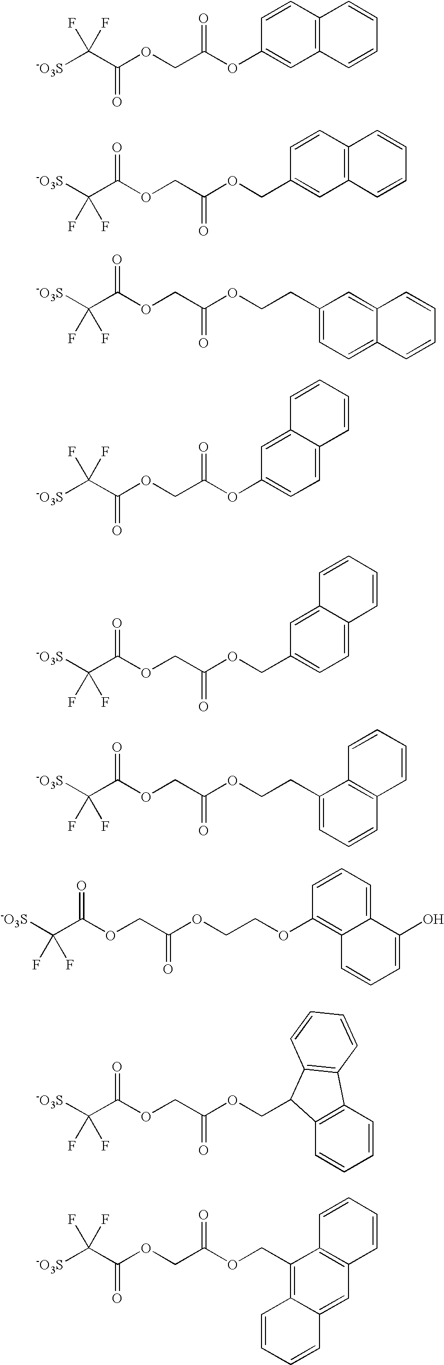

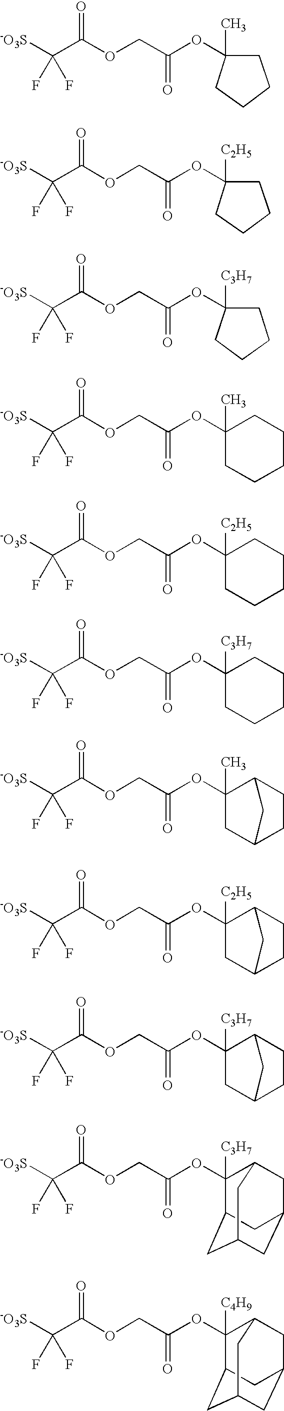

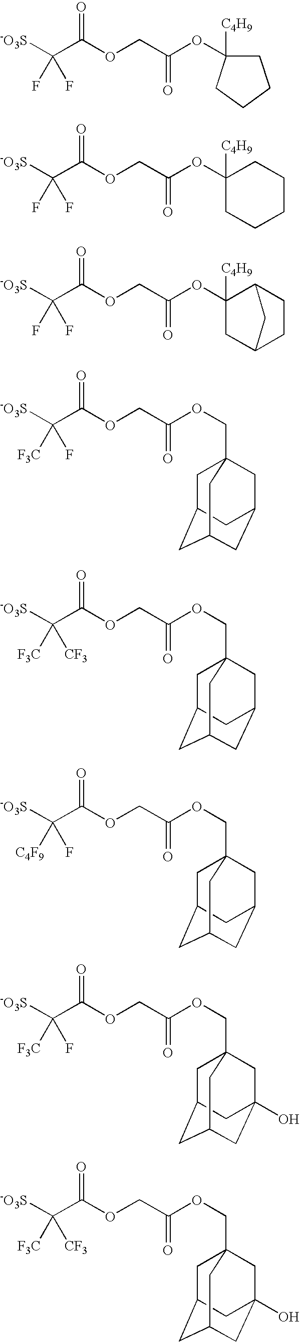

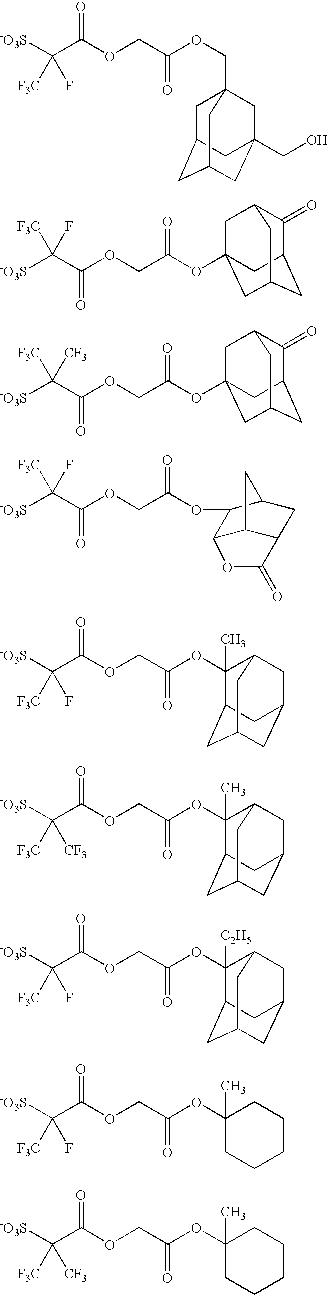

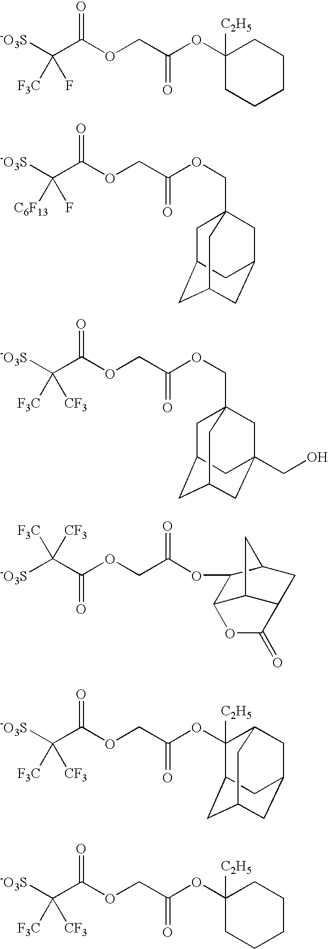

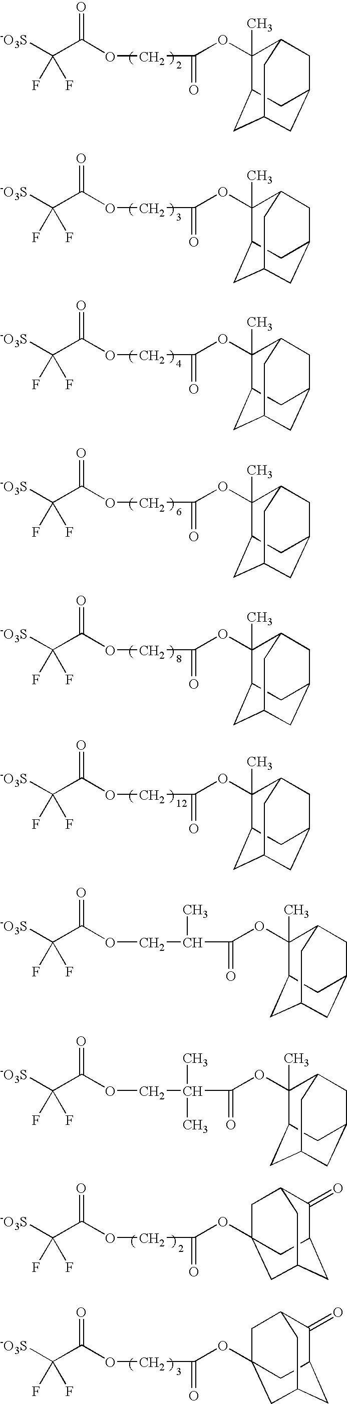

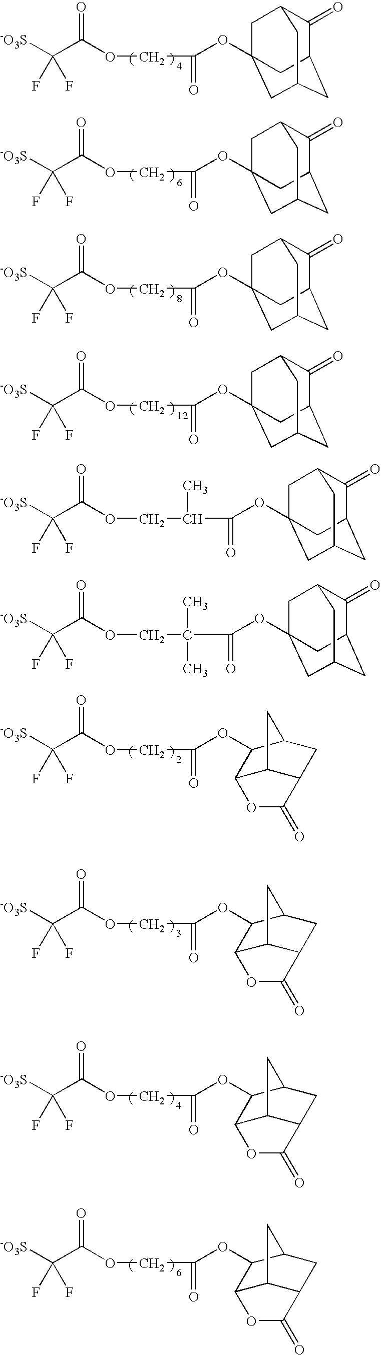

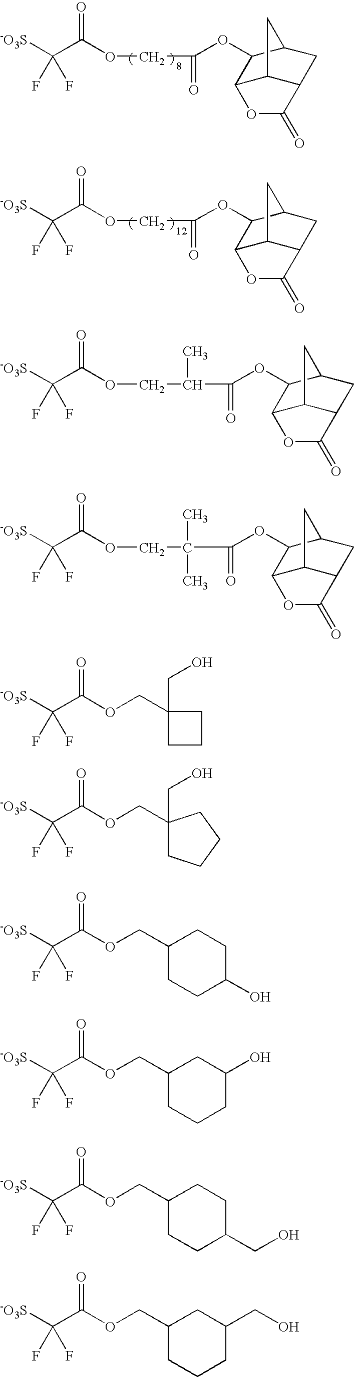

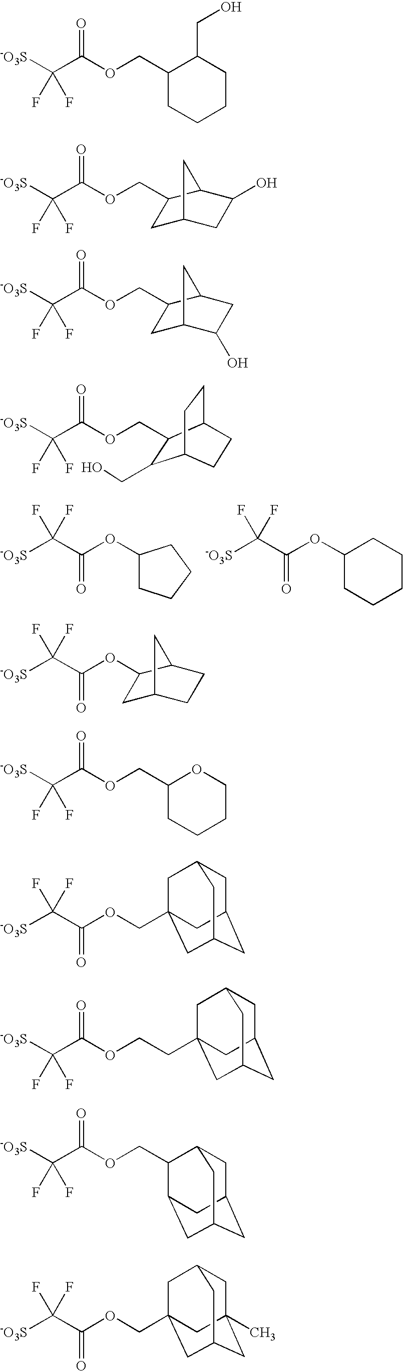

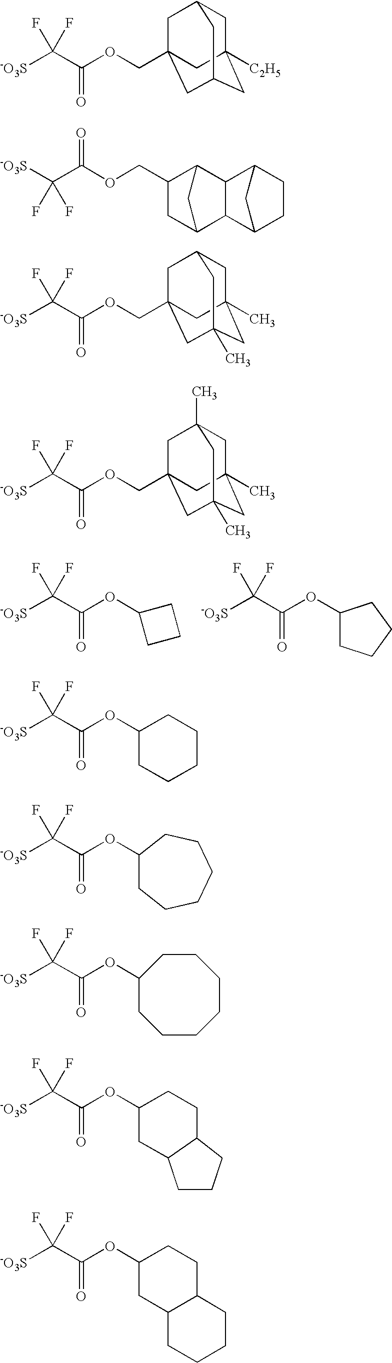

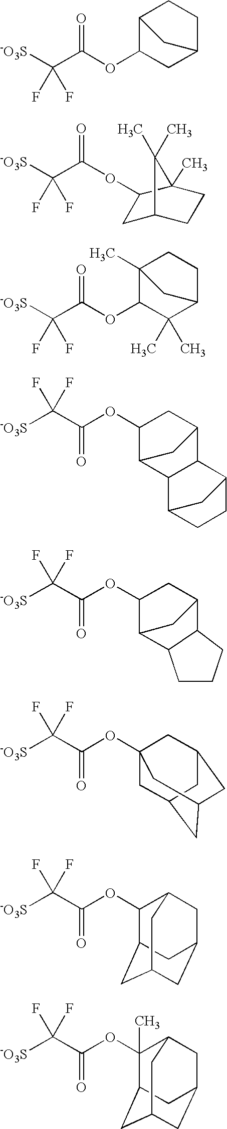

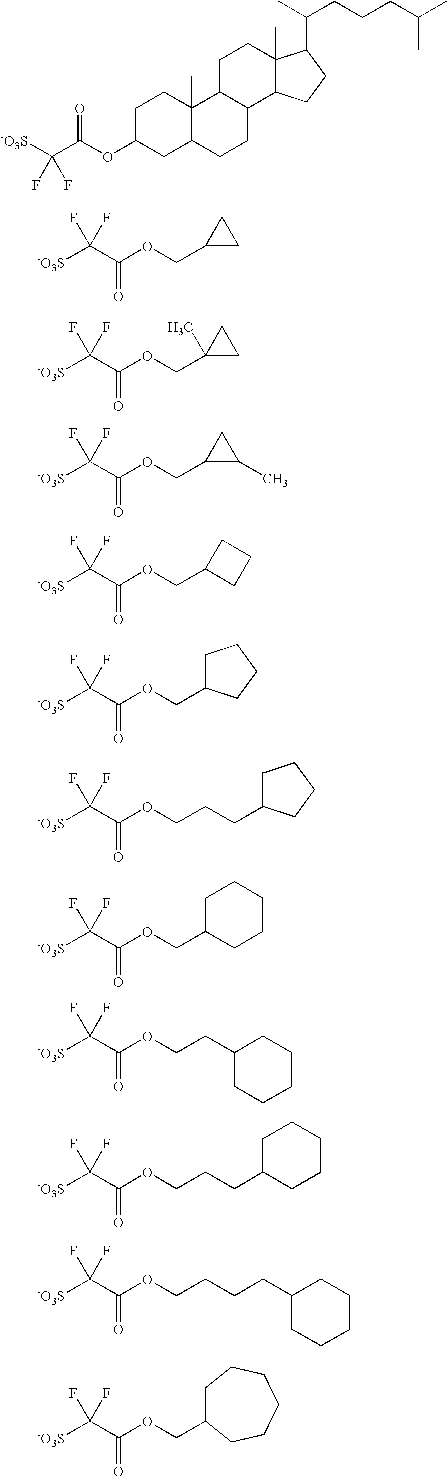

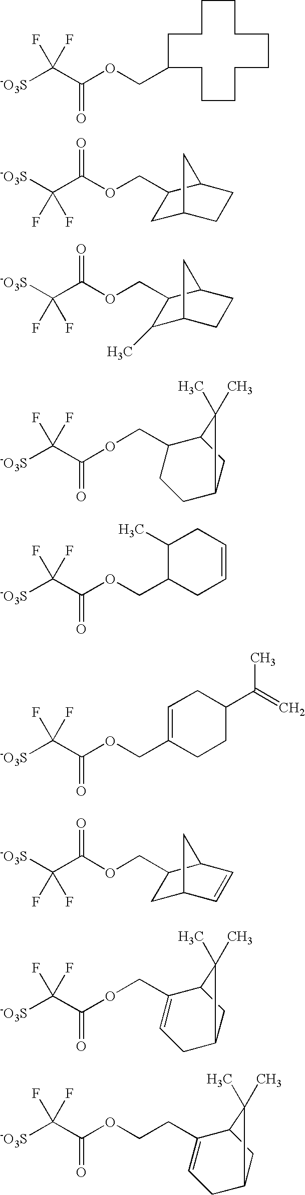

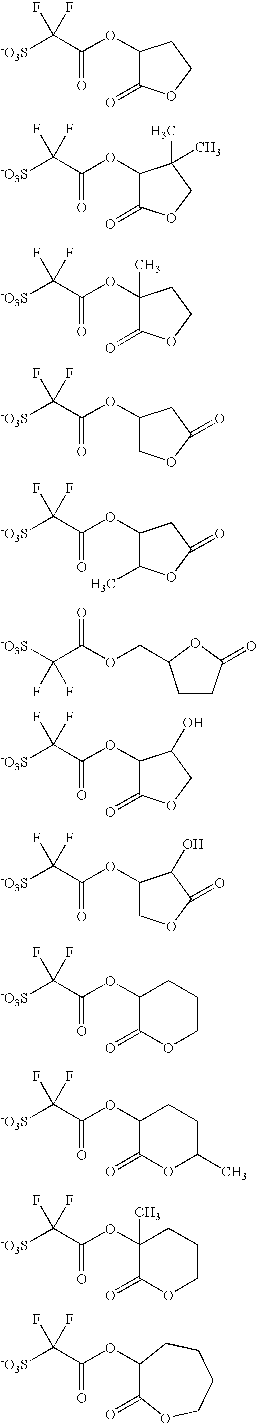

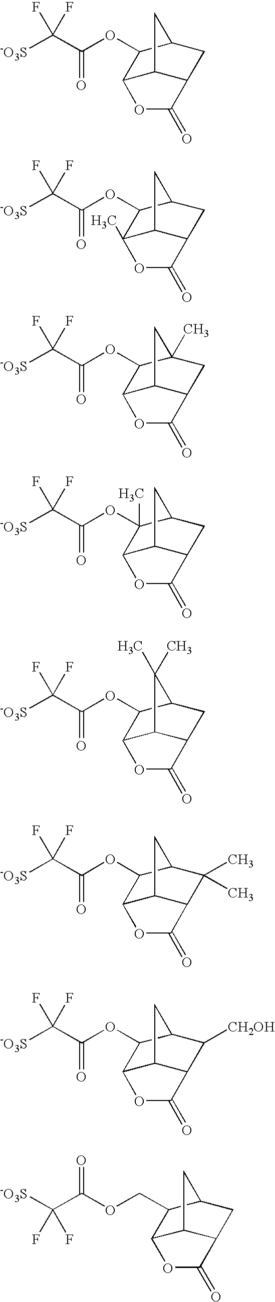

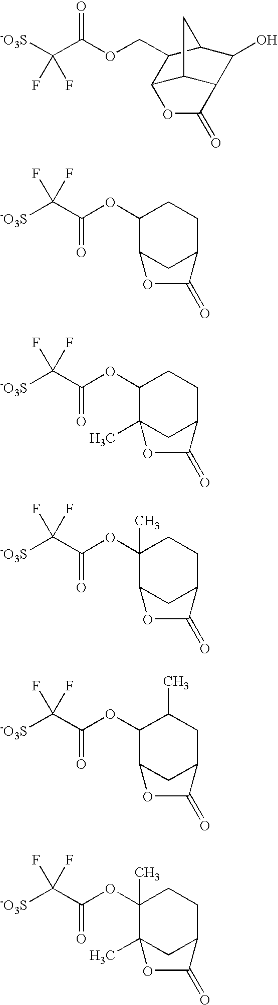

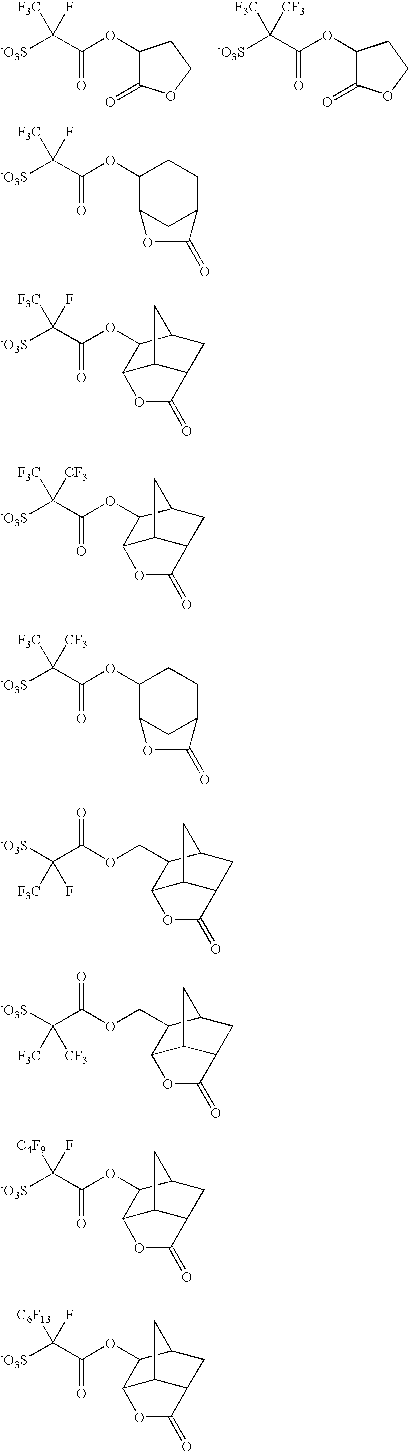

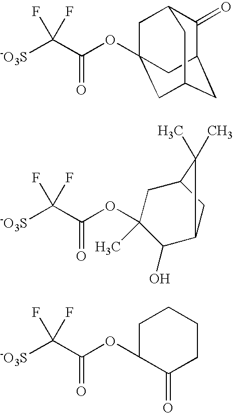

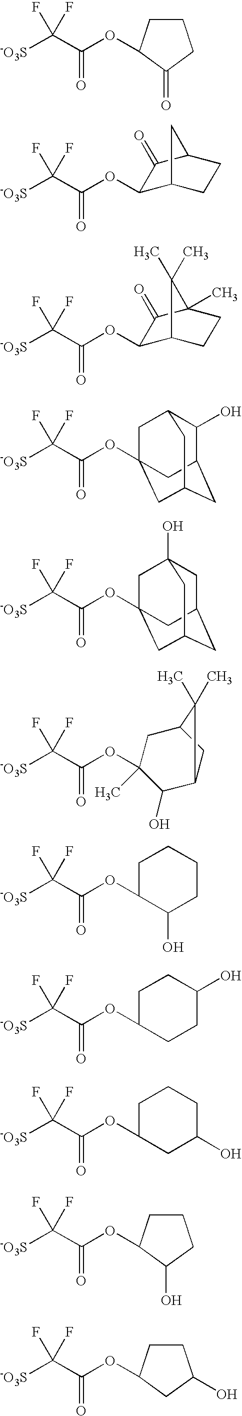

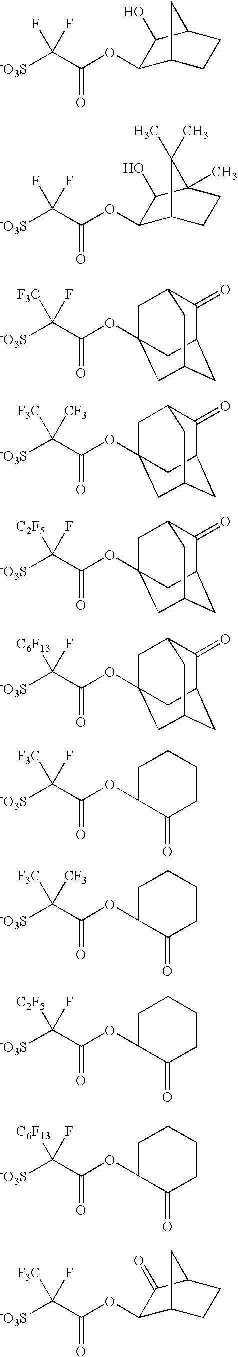

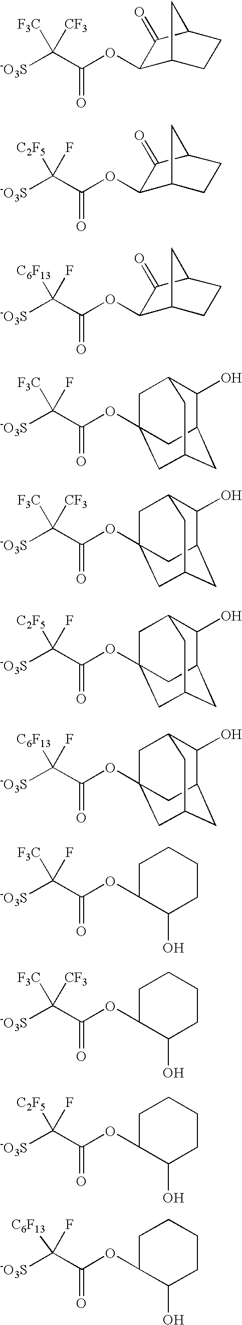

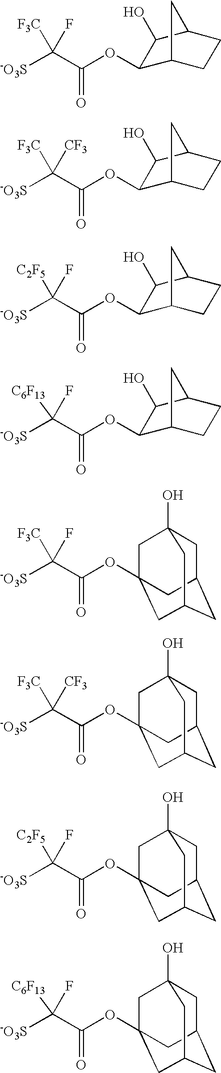

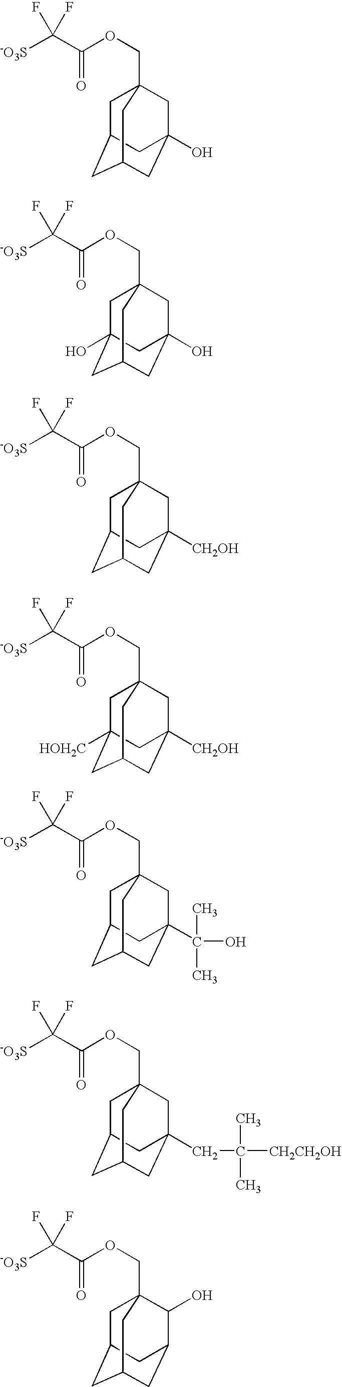

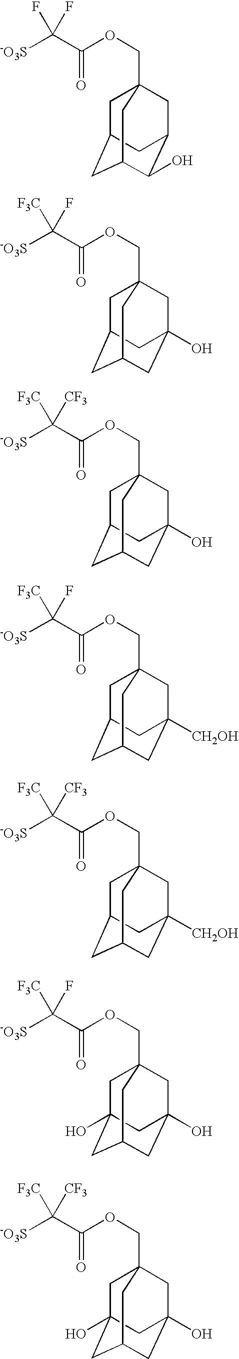

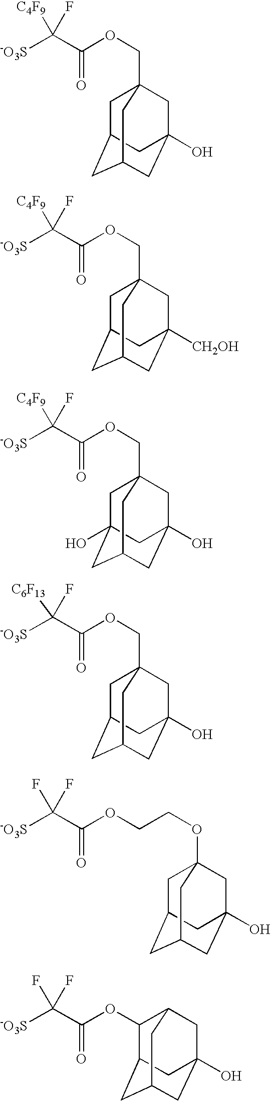

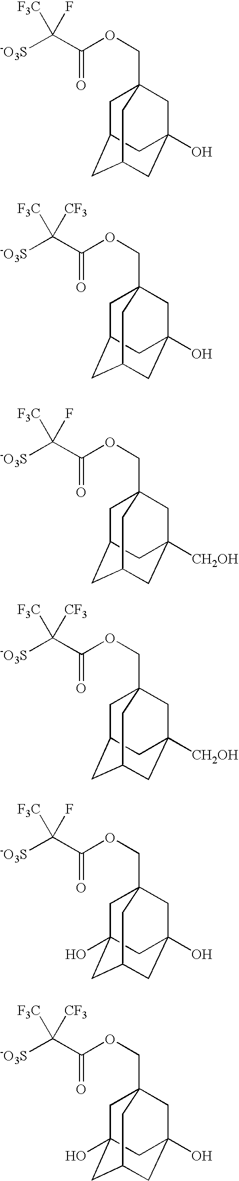

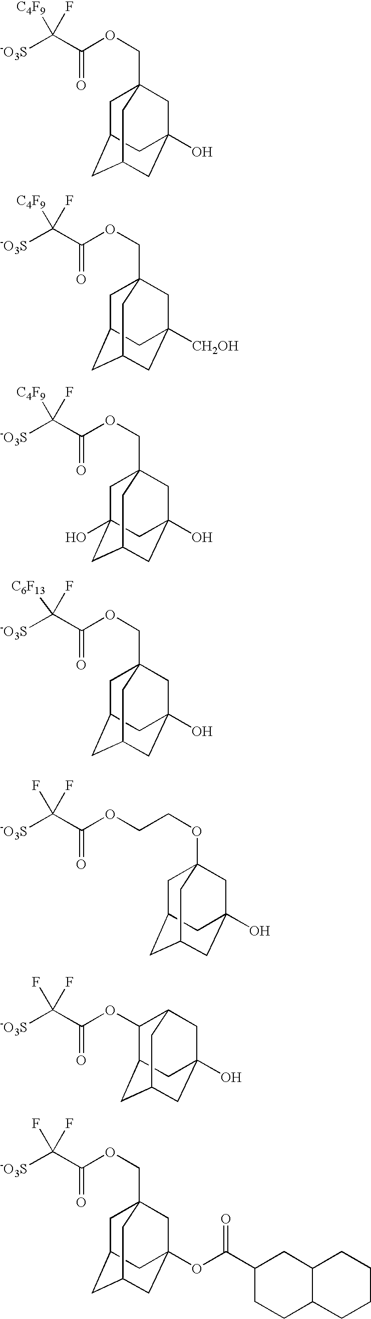

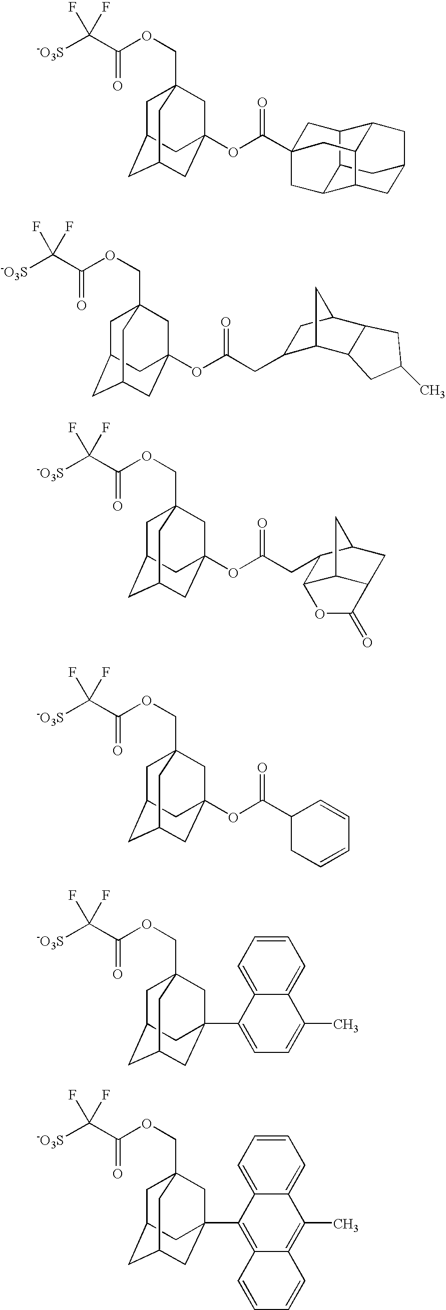

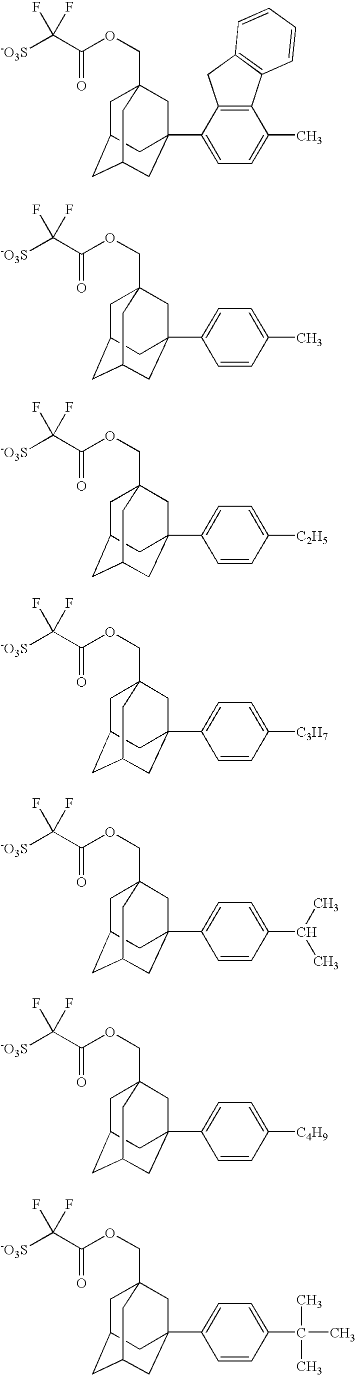

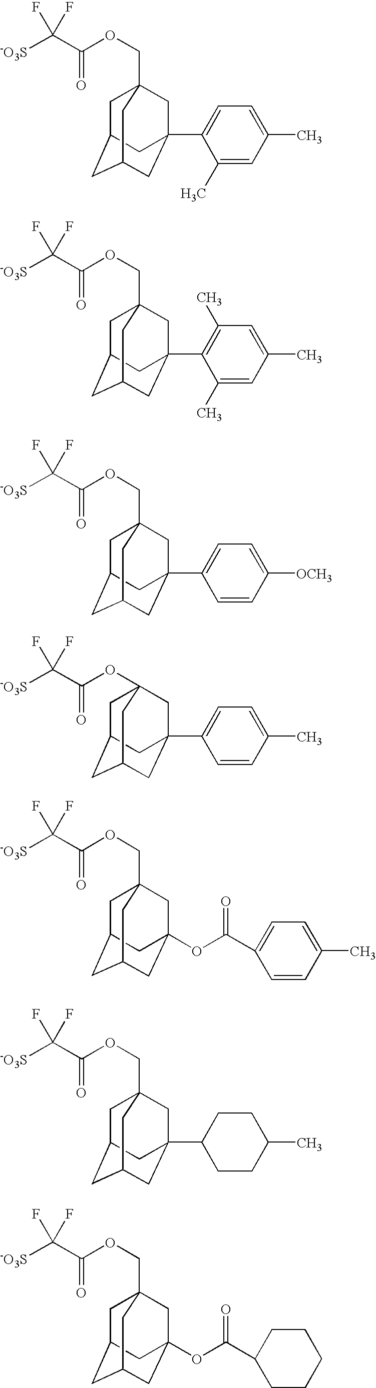

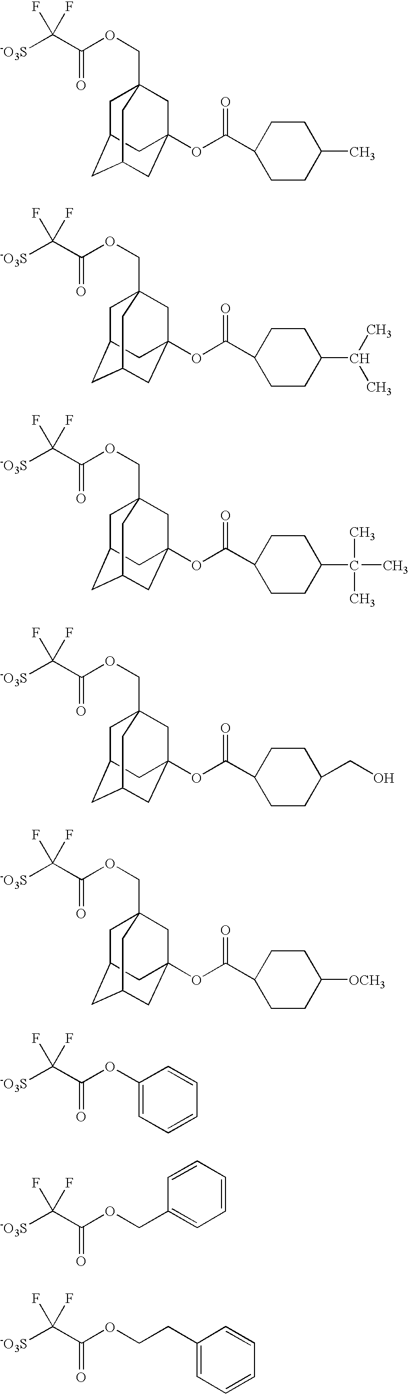

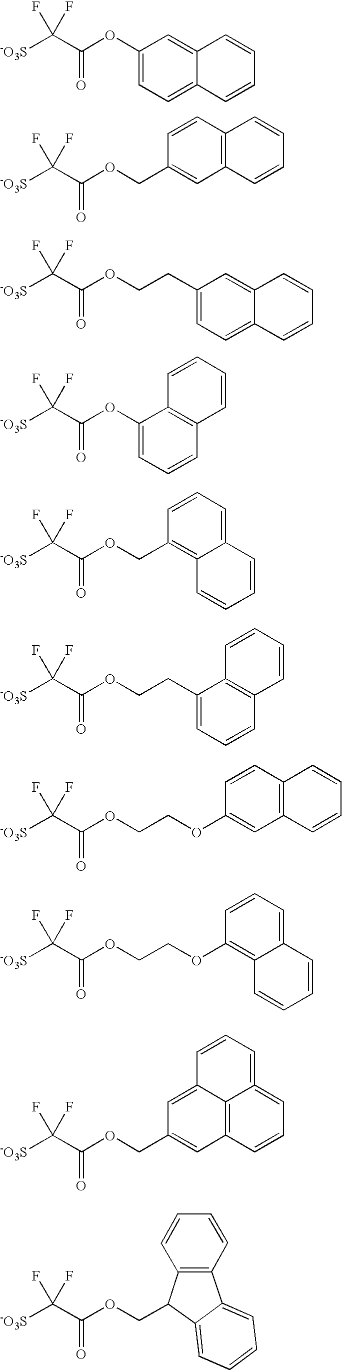

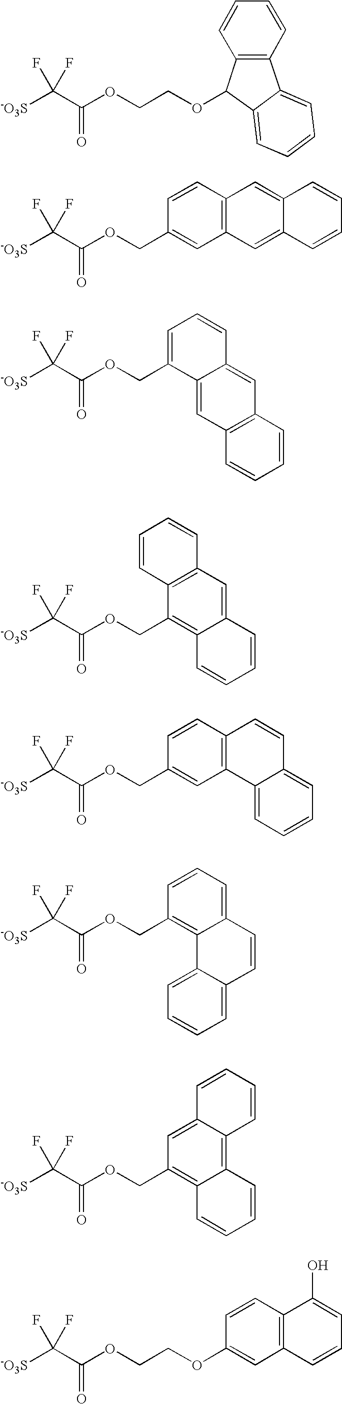

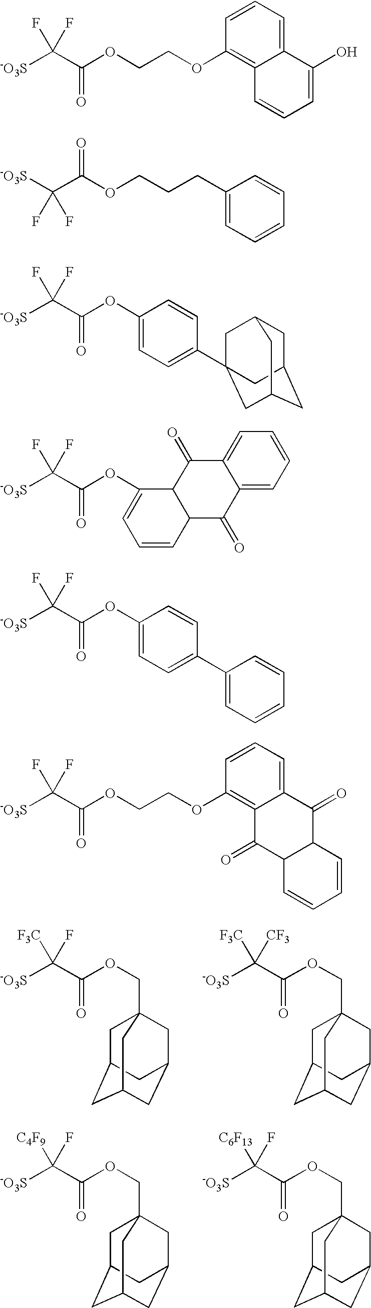

Among Salt (V), a salt represented by the formula (VI):

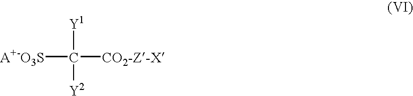

wherein Y1, Y2 and A+ are the same meanings as defined above, Z′ represents a single bond or a C1-C4 alkylene group, and X′ represents a C3-C30 monocyclic or polycyclic hydrocarbon group having a hydroxyl group or a carbonyl group, and one or more hydrogen atoms in the monocyclic or polycyclic hydrocarbon group may be replaced by a C1-C6 alkoxy group, a C1-C4 perfluoroalkyl group, a C1-C6 hydroxyalkyl group, a hydroxyl group or a cyano group (hereinafter, simply referred to as Salt (VI)) is preferable.

Examples of the C1-C6 alkoxy group, the C1-C4 perfluoroalkyl group and the C1-C6 hydroxyalkyl group in X′ include the same groups as described above, respectively.

Examples of the C1-C4 alkylene group in Z′ include a methylene group, an ethylene group, a trimethylene group and a tetramethylen group. Z′ is preferably a single bond, a methylene group or an ethylene group, and is more preferable a single bond or a methylene group.

Examples of X′ include a C4-C8 cycloalkyl group such as a cyclobutyl group, a cyclopentyl group, a cyclohexyl group and a cyclooctyl group, an adamantyl group, and a norbornyl group, in all of which one or more hydrogen atoms may be replaced by the C1-C6 alkoxy group, the C1-C4 perfluoroalkyl group, the C1-C6 hydroxyalkyl group, a hydroxyl group or a cyano group.

Specific examples of X′ include a 2-oxocyclopentyl group, a 2-oxocyclohexyl group, a 3-oxocyclopentyl group, a 3-oxocyclohexyl group, a 4-oxocyclohexyl group, a 2-hydroxycyclopentyl group, a 2-hydroxycyclohexyl group, a 3-hydroxycyclopentyl group, a 3-hydroxycyclohexyl group, a 4-hydroxycyclohexyl group, a 4-oxo-2-adamantyl group, a 3-hydroxy-1-adamantyl group, a 4-hydroxy-1-adamantyl group, a 5-oxonorbornan-2-yl group, a 1,7,7-trimethyl-2-oxonorbornan-2-yl group, a 3,6,6-trimethyl-2-oxo-bicyclo[3.1.1]heptan-3-yl group, a 2-hydroxy-norbornan-3-yl group, a 1,7,7-trimethyl-2-hydroxynorbornan-3-yl group, a 3,6,6-trimethyl-2-hydroxybicyclo[3.1.1]heptan-3-yl group, and the following groups (in the following formulae, straight line with an open end shows a bond which is extended from an adjacent group).

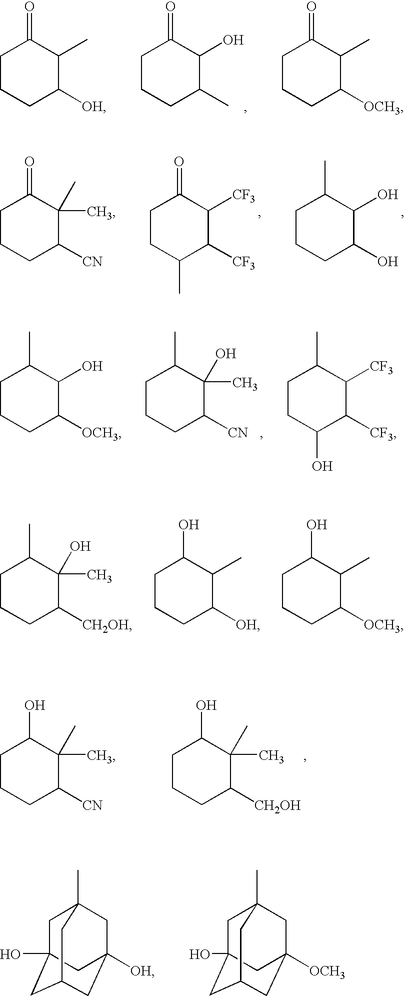

Specific examples of the anion part of Salt (VI) include the followings.

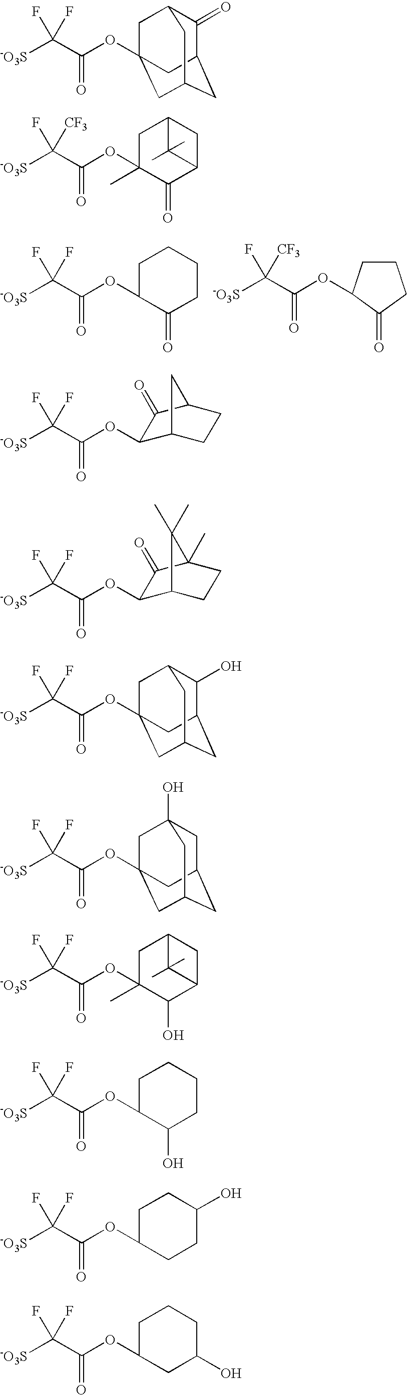

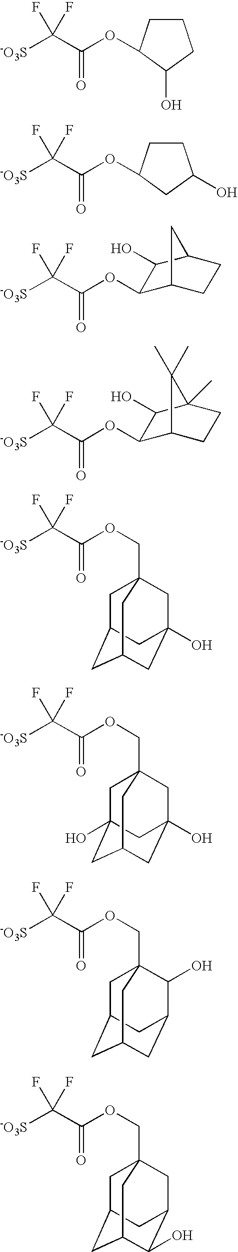

Other examples of the acid generator include a salt represented by the formula (VII):

A⁺⁻O₃S—R¹³ (VIII)

wherein R¹³ represents a linear or branched chain C1-C6 perfluoroalkyl group and A⁺ is the same as defined above (hereinafter, simply referred to as Salt (VIII)).

In Salt (VIII), examples of the linear or branched chain C1-C6 perfluoroalkyl group include a trifluoromethyl group, a pentafluoroethyl group, a heptafluoropropyl group, a nonafluorobutyl group and a tetradecafluorohexyl group.

Specific examples of the anion part of Salt (VIII) include the followings.
CF₃—SO₃⁻
CF₃CF₂CF₂—SO₃⁻
CF₃CF₂CF₂CF₂—SO₃⁻
CF₃CF₂CF₂CF₂CF₂CF₂—SO₃⁻

In Salt (V), Salt (VI) and Salt (VIII), A⁺ represents an organic counter ion. Examples of the organic counter ion include a cation represented by the formula (IXz):

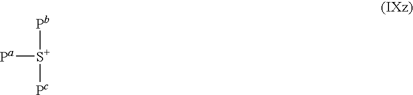

wherein P^{a}, P^{b} and P^{c} each independently represent a C1-C30 linear or branched chain alkyl group which may be have at least one substituent selected from the group consisting of a hydroxyl group, a C3-C12 cyclic hydrocarbon group and a C1-C12 alkoxy group, or a C3-C30 cyclic hydrocarbon group which may have at least one substituent selected from the group consisting of a hydroxyl group and a C1-C12 alkoxy group (hereinafter, simply referred to as the cation (IXz)), a cation represented by the formula (IXb):

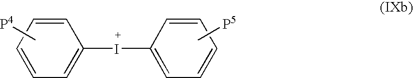

wherein P⁴ and P⁵ each independently represent a hydrogen atom, a hydroxyl group, a C1-C12 alkyl group or a C1-C12 alkoxy group (hereinafter, simply referred to as the cation (IXb)), a cation represented by the formula (IXc):

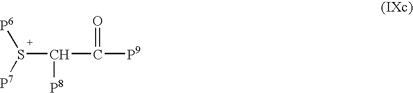

wherein P⁶ and P⁷ each independently represent a C1-C12 alkyl group or a C3-C12 cycloalkyl group, or P⁶ and P⁷ are bonded to form a C3-C12 divalent acyclic hydrocarbon group which forms a ring together with the adjacent S⁺, and one or more —CH₂— in the divalent acyclic hydrocarbon group may be replaced by —CO—, —O— or —S—, P⁹ represents a hydrogen atom, P⁹ represents a C1-C12 alkyl group, a C3-C12 cycloalkyl group or an aromatic group which may have one or more substituents, or P⁸ and P⁹ are bonded to form a divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S—, (hereinafter, simply referred to as the cation (IXc)); and a cation represented by the formula (IXd):

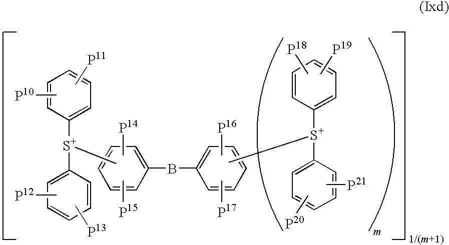

wherein P¹⁰, P¹¹, P¹², P¹³, P¹⁴, P¹⁵, P¹⁶, P¹⁷, P¹⁸, P¹⁹, P²⁰ and p²¹ each independently represent a hydrogen atom, a hydroxyl group, a C1-C12 alkyl group or a C1-C12 alkoxy group, B represents a sulfur or oxygen atom and m represents 0 or 1 (hereinafter, simply referred to as the cation (IXd)).

Examples of the C1-C12 alkoxy group in the cations (IXz), (IXb) and (IXd) include a methoxy group, an ethoxy group, an n-propoxy group, an isopropoxy group, an n-butoxy group, an isobutoxy group, a sec-butoxy group, a tert-butoxy group, an n-pentyloxy group, an n-hexyloxy group, an n-octyloxy group and a 2-ethylhexyloxy group.

Examples of the C3-C12 cyclic hydrocarbon group in the cation (IXz) include a cyclopentyl group, a cyclohexyl group, a 1-adamantyl group, a 2-adamantyl group, a phenyl group, a 2-methylphenyl group, a 4-methylphenyl group, a 1-naphthyl group and a 2-naphthyl group.

Examples of the C1-C30 alkyl group which may have at least one substituent selected from the group consisting of a hydroxyl group, a C3-C12 cyclic hydrocarbon group and a C1-C12 alkoxy group in the cation (IXz) include a methyl group, an ethyl group, an n-propyl group, an isopropyl group, an n-butyl group, an isobutyl group, a sec-butyl group, a tert-butyl group, an n-pentyl group, an n-hexyl group, an n-octyl group, a 2-ethylhexyl group and a benzyl group.

Examples of the C3-C30 cyclic hydrocarbon group which may have at least one substituent selected from the group consisting of a hydroxyl group and a C1-C12 alkoxy group in the cation (IXz) include a cyclopentyl group, a cyclohexyl group, a 1-adamantyl group, a 2-adamantyl group, a bicyclohexyl group, a phenyl group, a 2-methylphenyl group, a 4-methylphenyl group, a 4-ethylphenyl group, a 4-isopropylphenyl group, a 4-tert-butylphenyl group, a 2,4-dimethylphenyl group, a 2,4,6-trimethylphenyl group, a 4-n-hexylphenyl group, a 4-n-octylphenyl group, a 1-naphthyl group, a 2-naphthyl group, a fluorenyl group, a 4-phenylphenyl group, a 4-hydroxyphenyl group, a 4-methoxyphenyl group, a 4-tert-butoxyphenyl group and a 4-n-hexyloxyphenyl group.

Examples of the C1-C12 alkyl group in the cations (IXb), (IXc) and (IXd) include a mlethyl group, an ethyl group, an n-propyl group, an isopropyl group, an n-butyl group, an isobutyl group, a sec-butyl group, a tert-butyl group, an n-pentyl group, an n-hexyl group, an n-octyl group and a 2-ethylhexyl group.

Examples of the C3-C12 cycloalkyl group in the cation (IXc) include a cyclopropyl group, a cyclobutyl group, a cyclopentyl group, a cyclohexyl group, a cycloheptyl group, a cyclooctyl group and a cyclodecyl group. Examples of the C3-C12 divalent acyclic hydrocarbon group formed by bonding P⁶ and P⁷ include a trimethylene group, a tetramethylene group and a pentamethylene group. Examples of the ring group formed together with the adjacent S⁺ and the divalent acyclic hydrocarbon group include a tetramethylenesulfonio group, a pentamethylenesulfonio group and oxybisethylenesulfonio group.

Examples of the aromatic group in the cation (IXc) include a phenyl group, a tolyl group, a xylyl group, a 4-n-butylphenyl group, a 4-isobutylphenyl group, a 4-tert-butylphenyl group, a 4-cyclohexylphenyl group, a 4-phenylphenyl group, a 1-naphthyl group and a 2-naphthyl group. The aromatic group may have one or more substituents, and examples of the substituents include a C1-C6 alkoxy group such as a methoxy group, an ethoxy group, an n-propoxy group, an n-butoxy group, a tert-butoxy group and an n-hexyloxy group; a C2-C12 acyloxy group such as an acetyloxy group and a 1-adamantylcarbonyloxy group; and a nitro group.

Examples of the divalent acyclic hydrocarbon group formed by bonding P⁸ and P⁹ include a methylene group, an ethylene group, a trimethylene group, a tetramethylene group and a pentamethylene group and examples of the 2-oxocycloalkyl group formed together with the adjacent —CHCO— and the divalent acyclic hydrocarbon group include a 2-oxocyclopentyl group and a 2-oxocyclohexyl group.

Examples of the cation (IXz) include the followings:

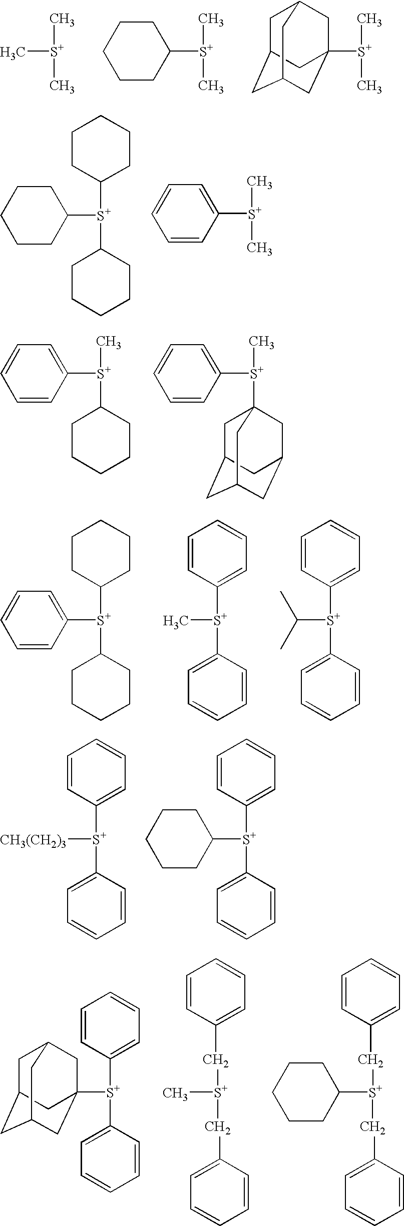

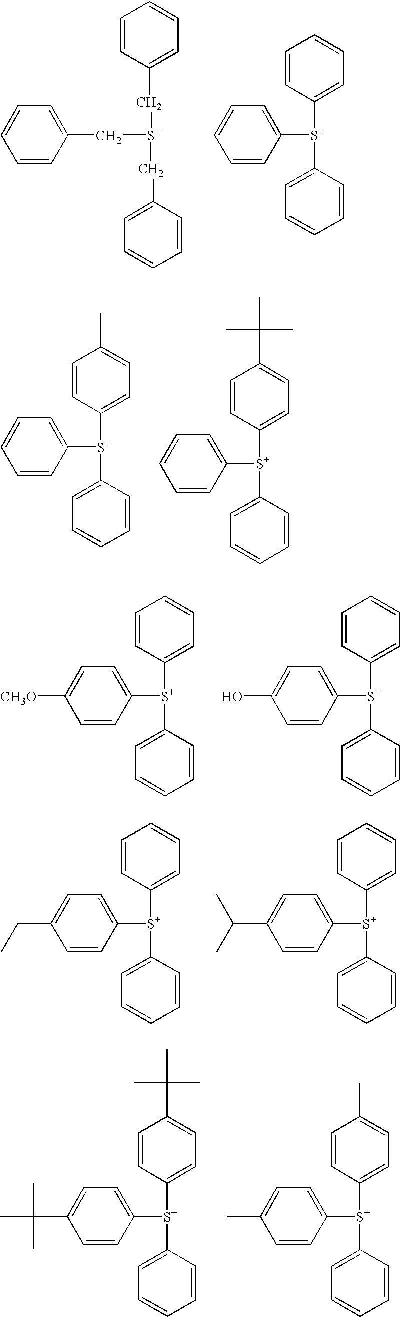

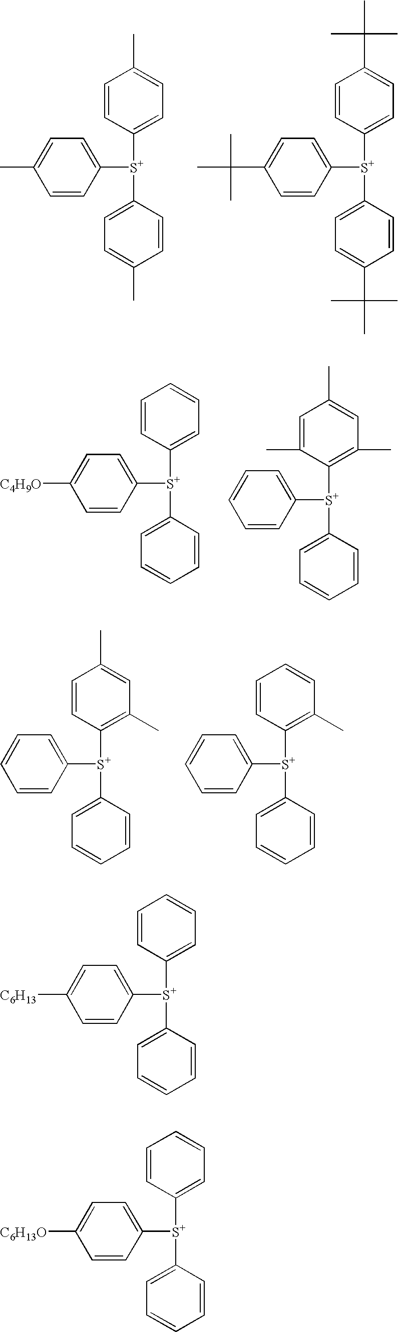

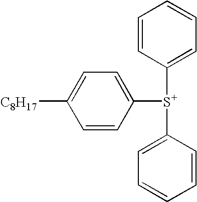

Specific examples of the cation (IXb) include the following.

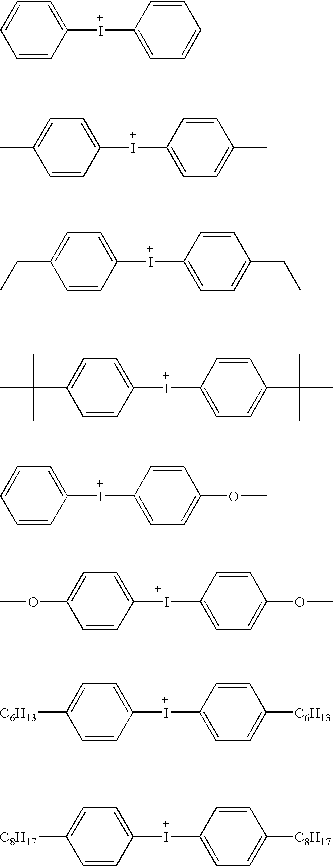

Specific examples of the cation (IXc) include the following:

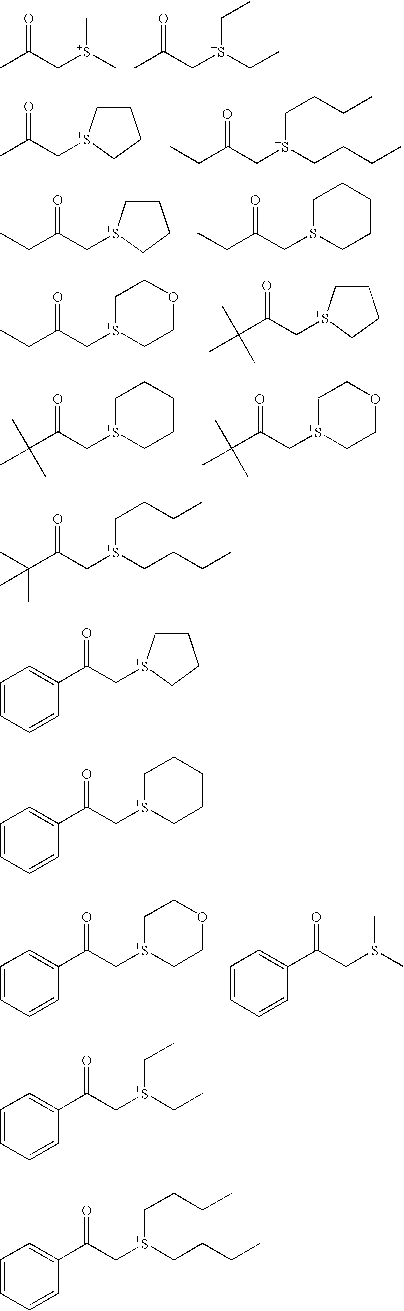

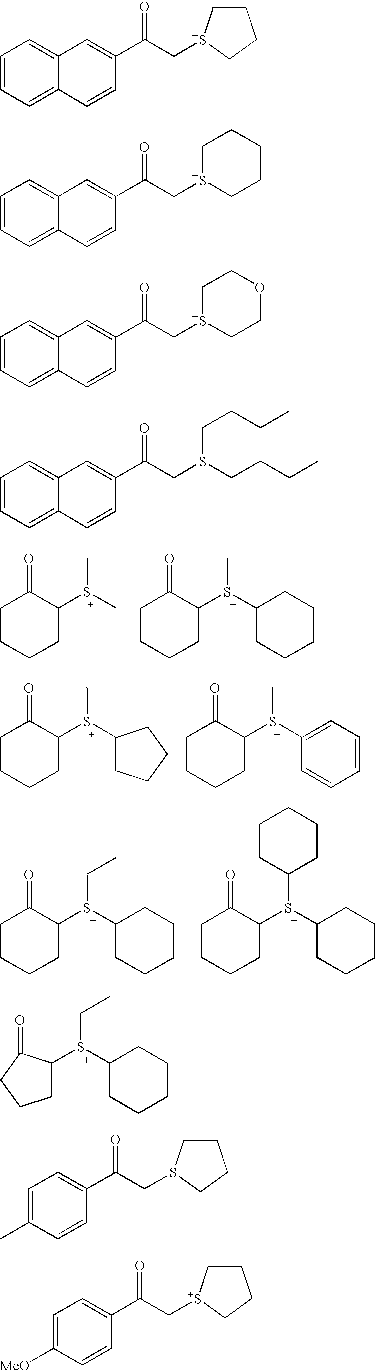

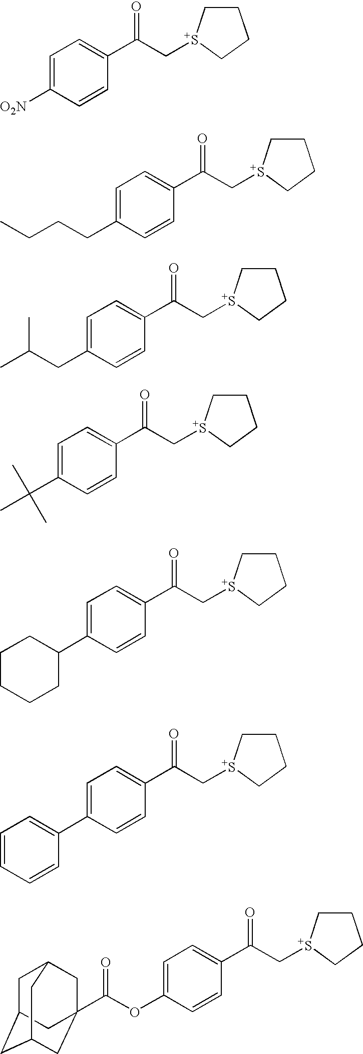

Specific examples of the cation (IXd) include the following:

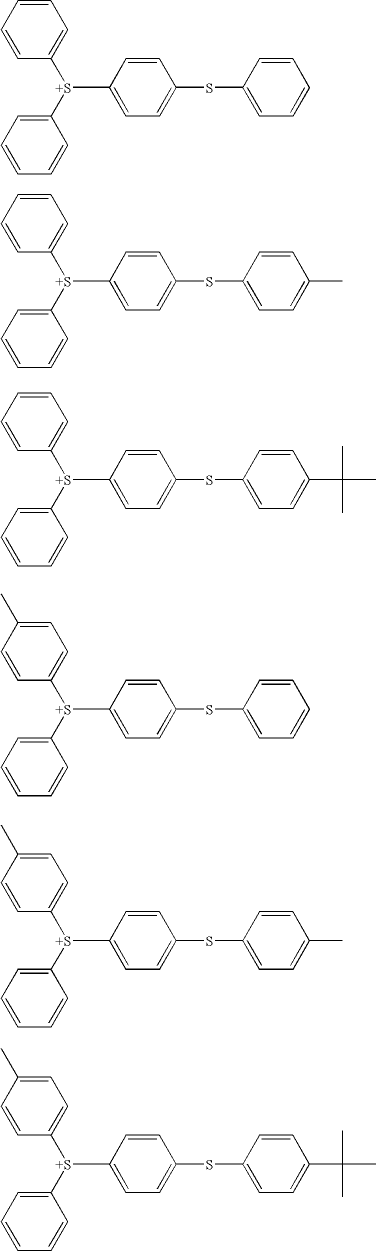

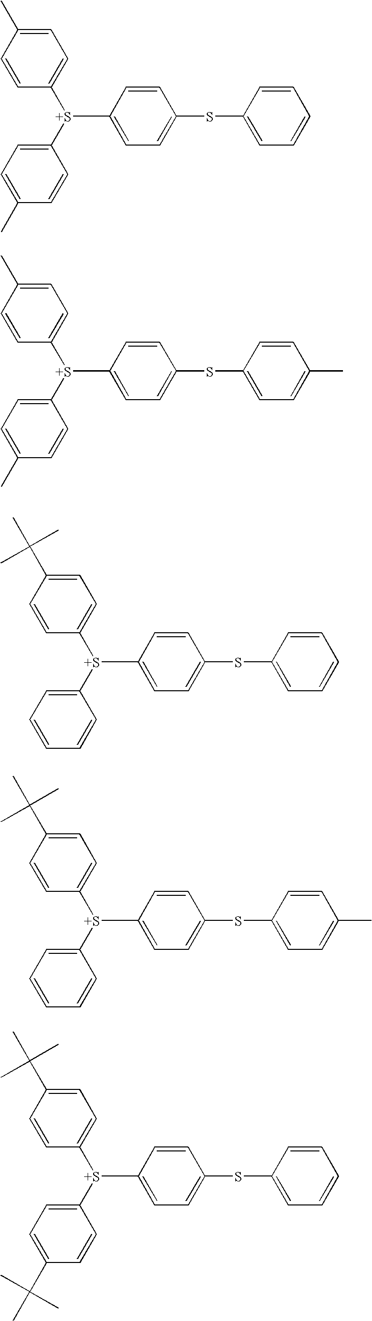

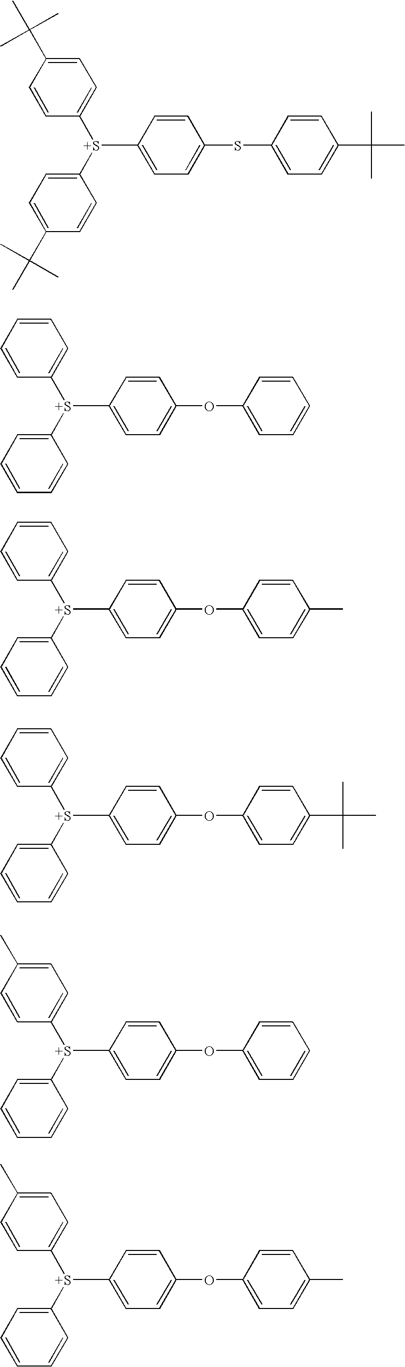

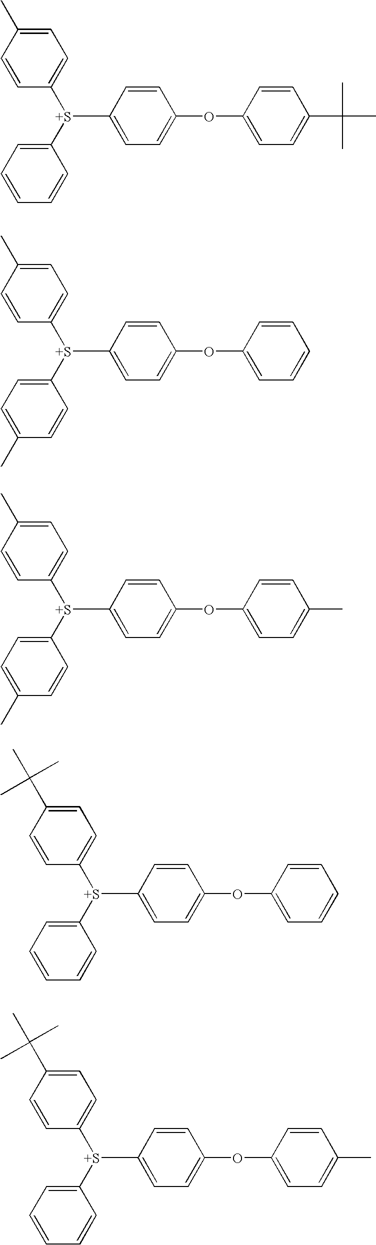

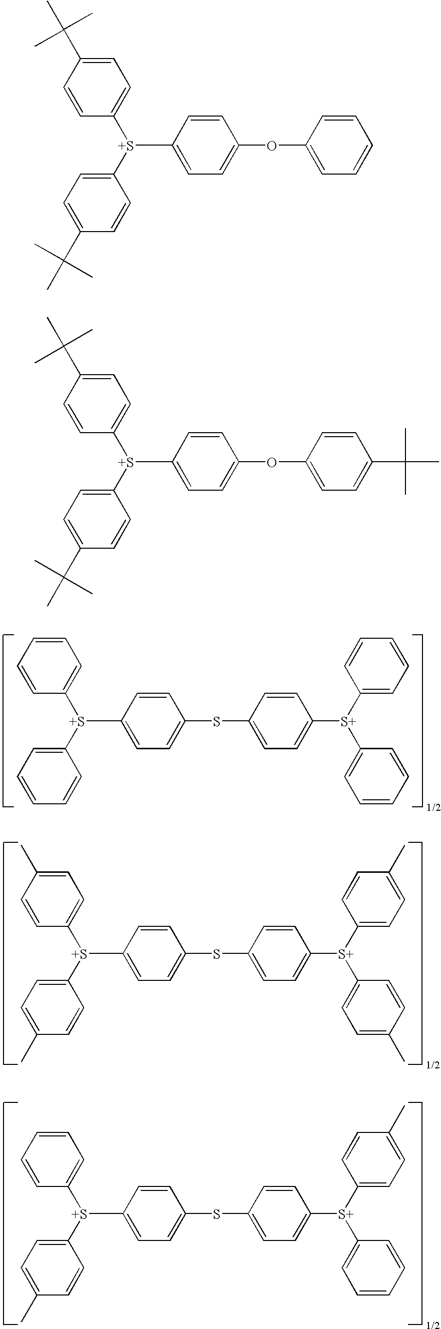

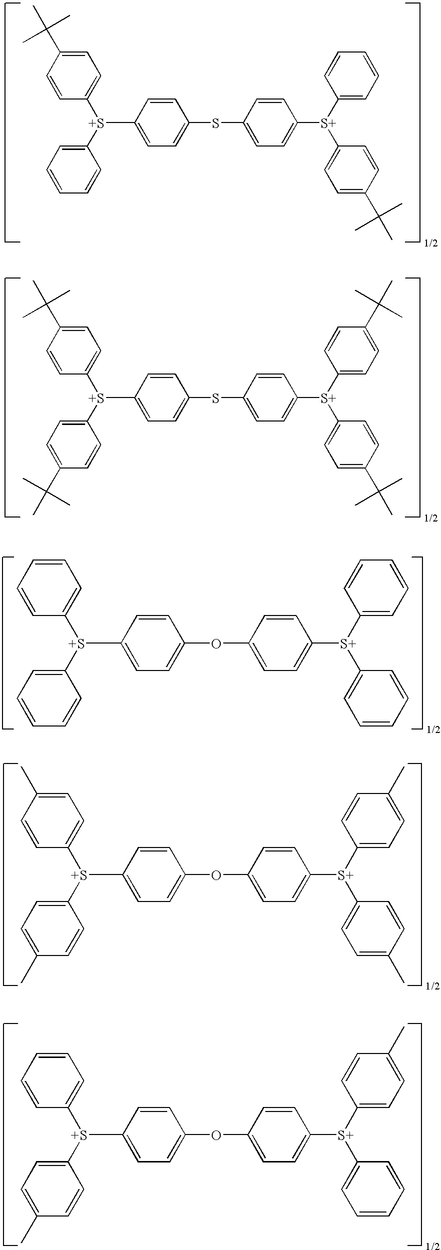

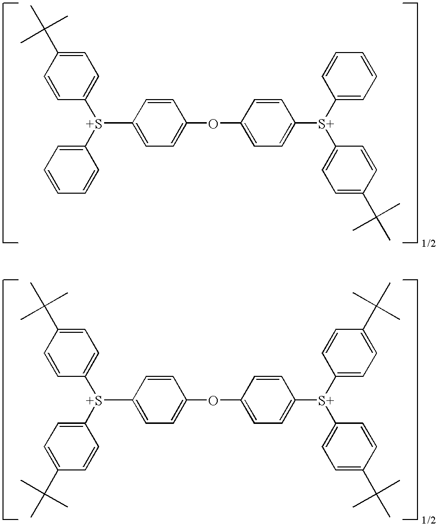

Among the cation (IXz), the cation represented by the formula (Ixa):

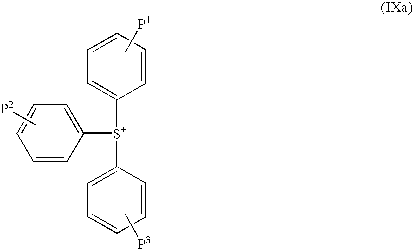

wherein P¹ , P² and P³ each independently represent a hydrogen atom, a hydroxyl group, a C1-C12 linear or branched chain alkyl group or a C1-C12 linear or branched chain alkoxy group, is preferable. Examples of the C1-C12 linear or branched chain alkyl group and the C1-C12 linear or branched chain alkoxy group include the same as described above.

As the organic counter ion represented by A⁺, a cation represented by the following formulae (IXe):

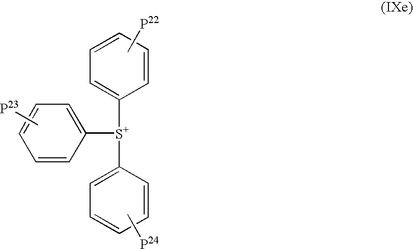

wherein P²², P²³ and P²⁴ each independently represent a hydrogen atom or a C1-C4 alkyl group, is also preferable.

As the Salt (VI) r a salt wherein A⁺ is the cation represented by the following formulae (IXe) and the anion part is the following:

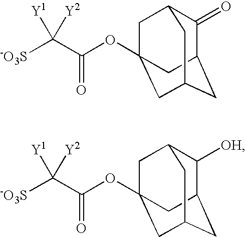

and a salt wherein A⁺ is the cation represented by the following formulae (IXc) and the anion part is the following:

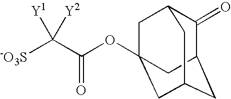

are preferable.

Salt (VI) can be produced according to known methods such as a method described in JP 2007-249192 A1.

The present resist composition preferably includes 80 to 99.9% by weight of the polymer of the present invention and 0.1 to 20% by weight of the acid generator based on the total amount of the polymer of the present invention and the acid generator.

In the present resist composition, performance deterioration caused by inactivation of acid which occurs due to post exposure delay can be diminished by adding an organic base compound, particularly a nitrogen-containing organic base compound as a quencher.

Specific examples of the nitrogen-containing organic base compound include an amine compound represented by the following formulae:

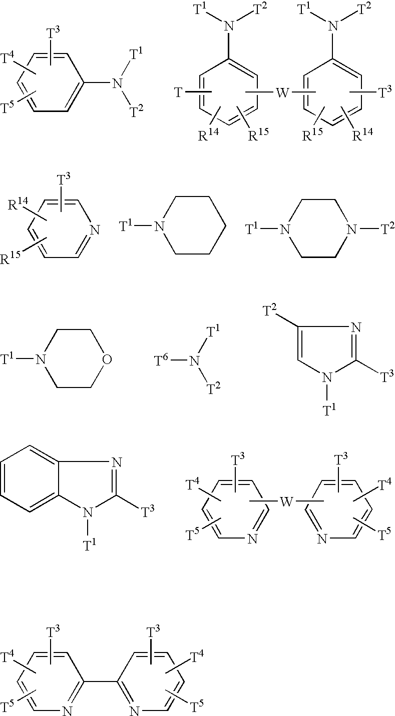

wherein T¹ and T¹² independently represent a hydrogen atom, an alkyl group, a cycloalkyl group or an aryl group, and one or more hydrogen atoms in the alkyl, cycloalkyl and aryl groups may be substituted with a hydroxyl group, an amino group which have one or two C1-C4 alkyl groups, or a C1-C6 alkoxy group,
T³ and T⁴ independently represent a hydrogen atom, an alkyl group, a cycloalkyl group, an aryl group or an alkoxy group, and one or more hydrogen atoms of the alkyl, cycloalkyl, aryl and alkoxy groups may be substituted with a hydroxyl group, an amino group which may have one or more C1-C4 alkyl groups or a C1-C6 alkoxy group, or T³ and T⁴ bond together with the carbon atoms to which they bond to form an aromatic ring,
T⁵ represent a hydrogen atom, an alkyl group, a cycloalkyl group, an aryl group, an alkoxy group or a nitro group, and one or more hydrogen atoms of the alkyl, cycloalkyl, aryl and alkoxy groups may be substituted with a hydroxyl group, an amino group which may have one or two C1-C4 alkyl groups or a C1-C6 alkoxy group, T⁶ represents an alkyl group or a cycloalkyl group, and one or more hydrogen atoms of the alkyl and cycloalkyl groups may be substituted with a hydroxyl group, an amino group which may have one or two C1-C4 alkyl groups or a C1-C6 alkoxy group, and
W represents —CO—, —NH—, —S—, —S—S—, an alkylene group of which one or more —CH₂— may be replaced by —O—, or an alkenylene group of which one or more —CH₂— may be replaced by —O—,
and a quaternary ammonium hydroxide represented by the following formula:

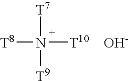

wherein T⁷, T⁸, T⁹ and T¹⁰ independently represent an alkyl group, a cycloalkyl group or an aryl group, and one or more hydrogen atoms of the alkyl, cycloalkyl and aryl groups may be substituted with a hydroxyl group, an amino group which may have one or two C1-C4 alkyl groups or a C1-C6 alkoxy group.

The alkyl group in T¹, T², T³, T⁴, T⁵, T⁶, T⁷, T⁸, T⁹ and T¹⁰ preferably has about 1 to 10 carbon atoms, and more preferably has about 1 to 6 carbon atoms.

Examples of the amino group which may have one or two C1-C4 alkyl groups include an amino group, a methylamino group, an ethylamino group, an n-butylamino group, a dimethylamino group and a diethylamino group. Examples of the C1-C6 alkoxy group of which one or more hydrogen atoms may be substituted with the C1-C6 alkoxy group include a methoxy group, an ethoxy group, an n-propoxy group, an isopropoxy group, an n-butoxy group, a tert-butoxy group, an n-pentyloxy group, an n-hexyloxy group and a 2-methoxyethoxy group.

Specific examples of the alkyl group of which one or more hydrogen atoms may be substituted with a hydroxyl group, an amino group which may have one or two C1-C4 alkyl groups, or a C1-C6 alkoxy group of which one or more hydrogen atoms may be substituted with a C1-C6 alkoxy group include a methyl group, an ethyl group, an n-propyl group, an isopropyl group, an n-butyl group, a tert-butyl group, an n-pentyl group, an n-hexyl group, an n-octyl group, an n-nonyl group, an n-decyl group, a 2-(2-methoxyethoxy) ethyl group, a 2-hydroxyethyl group, a 2-hydroxypropyl group, a 2-aminoethyl group, a 4-aminobutyl group and a 6-aminohexyl group.

The cycloalkyl group in T¹, T², T³, T⁴, T⁵, T⁶, T⁷, T⁸, T⁹ and T¹⁰ preferably has about 5 to 10 carbon atoms. Specific examples of the cycloalkyl group of which one or more hydrogen atoms may be substituted with a hydroxyl group, an amino group which may have one or two C1-C4 alkyl groups or a C1-C6 alkoxy group include a cyclopentyl group, a cyclohexyl group, a cycloheptyl group and a cyclooctyl group.

The aryl group in T¹, T², T³, T⁴, T⁵, T⁶, T⁷, T⁸, T⁹ and T¹⁰ preferably has about 6 to 10 carbon atoms. Specific examples of the aryl group of which one or more hydrogen atoms may be substituted with a hydroxyl group, an amino group which may have one or two C1-C4 alkyl groups or a C1-C6 alkoxy group include a phenyl group and a naphthyl group.

The alkoxy group in T³, T⁴ and T⁵ preferably has about 1 to 6 carbon atoms and specific examples thereof include a methoxy group, an ethoxy group, an n-propoxy group, an isopropoxy group, an n-butoxy group, a tert-butoxy group, an n-pentyloxy group and an n-hexyloxy group.

The alkylene and alkenylene groups in W preferably have 2 to 6 carbon atoms. Specific examples of the alkylene group include an ethylene group, a trimethylene group, a tetramethylene group, a methylenedioxy group and an ethylene-1,2-dioxy group, and specific examples of the alkenylene group include an ethene-1,2-diyl group, a 1-propene-1,3-diyl group and a 2-butene-1,4-diyl group.

Specific examples of the amine compound include n-hexylamine, n-heptylamine, n-octylamine, n-nonylamine, n-decylamine, aniline, 2-methylaniline, 3-methylaniline, 4-methylaniline, 4-nitroaniline, 1-naphthylamine, 2-naphthylamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylinethane, dibutylamine, dipentylamine, dihexylamine, diheptylamine, dioctylamine, dinonylamine, didecylamine, N-methylanilins, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, mathyldicyclohexylamine, methyldiheptylamine, methyldioctylamine, methyldinonylamine, methyldidecylamine, ethyldibutylamine, ethyldipentylamine, ethyldihexylamine, ethyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-diisopropylaniline, imidazole, benzimidazole, pyridine, 4-methylpyridine, 4-methylimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis (4-pyridyloxy)ethane, 4,4′-dipyridyl sulfide, 4,4′-dipyridyl disulfide, 1,2-bis(4-pyridyl)ethylene, 2,2′-dipicolylamine and 3,3′-dipicolylamine.

Examples of the quaternary ammonium hydroxide include tetramethylammonium hydroxide, tetraisopropylammonium hydroxide, tetrabutylammonium hydroxide, tetrahexylammonium hydroxide, tetraoctylammonium hydroxide, phenyltrimethylammonium hydroxide, (3-trifluoromethylphenyl) trimethylamnmoniuum hydroxide and (2-hydroxyethyl) trimethylammonium hydroxide (so-called “choline”).

A hindered amine compound having a piperidine skelton as disclosed in JP 11-52575 A1 can be also used as the quencher.

In the point of forming patterns having higher resolution, the quaternary ammonium hydroxide is preferably used as the quencher.

When the basic compound is used as the quencher, the present resist composition preferably includes 0.01 to 1% by weight of the basic compound based on the total amount of the polymer of the present invention and the acid generator.

The present resist composition can contain, if necessary, a small amount of various additives such as a sensitizer, a dissolution inhibitor, other polymers, a surfactant, a stabilizer and a dye as long as the effect of the present invention is not prevented.

The present resist composition is usually in the form of a resist liquid composition in which the above-mentioned ingredients are dissolved in a solvent and the resist liquid composition is applied onto a substrate such as a silicon wafer by a conventional process such as spin coating. The solvent used is sufficient to dissolve the above-mentioned ingredients, have an adequate drying rate, and give a uniform and smooth coat after evaporation of the solvent. Solvents generally used in the art can be used.

Examples of the solvent include a glycol ether ester such as ethyl cellosolve acetate, methyl cellosolve acetate and propylene glycol monomethyl ether acetate; a glycol ether such as propylene glycol monomethyl ether; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone. These solvents may be used alone and two or more thereof may be mixed to use.

A resist film applied onto the substrate and then dried is subjected to exposure for patterning, then heat-treated to facilitate a deblocking reaction, and thereafter developed with an alkali developer. The alkali developer used may be any one of various alkaline aqueous solution used in the art. Generally, an aqueous solution of tetramethylammonium hydroxide or (2-hydroxyethyl)trimethylammonium hydroxide (commonly known as “choline”) is often used.

It should be construed that embodiments disclosed here are examples in all aspects and not restrictive. It is intended that the scope of the present invention is determined not by the above descriptions but by appended claims, and includes all variations of the equivalent meanings and ranges to the claims.

The present invention will be described more specifically by way of examples, which are not construed to limit the scope of the present invention. The “%” and “part(s)” used to represent the content of any component and the amount of any material used in the following examples and comparative examples are on a weight basis unless otherwise specifically noted. The weight-average molecular weight of any material used in the following examples is a value found by gel permeation chromatography using polystyrene as a standard reference material.

### EXAMPLE 1

Into a four-necked flask equipped with stirrer and a thermometer, 12.0 parts of poly(p-hydroxystyrene), which was manufactured by Nippon Soda Co., Ltd. and which is called as “VP-8000”, was charged and 50 parts of acetone was added thereto. To the obtained solution, 13.8 parts of potassium carbonate, 1.7 parts of potassium iodide, 7.3 parts of 2-methyl-2-adamantyl chloroacetate and 5,5 parts of acetone were added, and the resultant mixture was stirred for 12 hours under reflux. The obtained reaction mixture was diluted with methyl isobutyl ketone, and neutralized with aqueous 1% oxalic acid solution. The obtained mixture was separated to an organic layer and an aqueous layer. The organic layer was washed with water and concentrated. The obtained residue was diluted with propylene glycol methyl ether acetate, and the resultant mixture was concentrated to obtain a polymer having a weight-average molecular weight (Mw) of 10,200 (equivalent to polystyrene) and dispersion degree of 1.12. This polymer had the structural units represented by the formulae (a) and (b) (hereinafter, simply referred to as Structural unit (a) and Structural unit (b), respectively). This is called as Polymer A1.

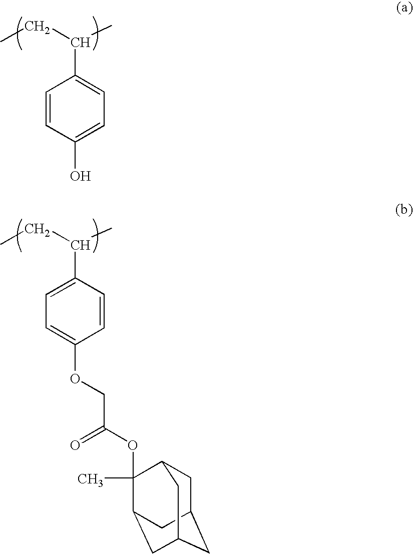

Molar ratio of the structural units in Polymer A1 was measured with ¹H-NMR and the result thereof was as followed:

Structural unit (a): Structural unit (b)=70.3:29.7

### EXAMPLE 2

Into a four-necked flask equipped with stirrer and a thermometer, 6.0 parts of poly(p-hydroxystyrene), which was manufactured by Nippon Soda Co., Ltd. and which is called as “VP-5000”, was charged and 34 parts of acetone was added thereto. To the obtained solution, 6.9 parts of potassium carbonate, 0.8 parts of potassium iodide, 6.7 parts of 2-methyl-2-adamantyl chloroacetate and 3.8 parts of acetone were added, and the resultant mixture was stirred for 12 hours under reflux. The obtained reaction mixture was diluted with methyl isobutyl ketone, and neutralized with aqueous 1% oxalic acid solution. The obtained mixture was separated to an organic layer and an aqueous layer. The organic layer was washed with water and concentrated. The obtained residue was diluted with propylene glycol methyl ether acetate, and the resultant mixture was concentrated to obtain a polymer having a weight-average molecular weight (Mw) of 6,800 (equivalent to polystyrene) and dispersion degree of 1.12. This polymer had Structural unit (a) and Structural unit (b). This is called as Polymer A2.

Molar ratio of the structural units in Polymer A2 was measured with ¹H-NMR and the result thereof was as followed:

Structural unit (a): Structural unit (b)=49.9: 50.1

### EXAMPLE 3

Into a four-necked flask equipped with stirrer and a thermometer, 9.0 parts of poly(p-hydroxystyrene), which was manufactured by Nippon Soda Co., Ltd. and which is called as “VP-2500”, was charged and 37 parts of acetone was added thereto. To the obtained solution, 10.4 parts of potassium carbonate, 1.3 parts of potassium iodide, 5.8 parts of 2-methyl-2-adamantyl chloroacetate and 4.2 parts of acetone were added, and the resultant mixture was stirred for 12 hours under reflux. The obtained reaction mixture was diluted with methyl isobutyl ketone, and neutralized with aqueous 1% oxalic acid solution. The obtained mixture was separated to an organic layer and an aqueous layer. The organic layer was washed with water and concentrated. The obtained residue was diluted with propylene glycol methyl ether acetate, and the resultant mixture was concentrated to obtain a polymer having a weight-average molecular weight (Mw) of 4,000 (equivalent to polystyrene) and dispersion degree of 1.20. This polymer had Structural unit (a) and Structural unit (b). This is called as Polymer A3.

Molar ratio of the structural units in Polymer A3 was measured with ¹H-NMR and the result thereof was as followed:

Structural unit (a): structural unit (b)=68.8:32.2

### EXAMPLE 4

Into a four-necked flask equipped with stirrer and a thermometer, 6.0 parts of poly(p-hydroxystyrene), which was manufactured by Nippon Soda Co., Ltd. and which is called as “VP-2500”, was charged and 24.9 parts of acetone was added thereto. To the obtained solution, 6.9 parts of potassium carbonate, 0.8 parts of potassium iodide, 6.7 parts of 2-methyl-2-adamantyl chloroacetate and 2.8 parts of acetone were added, and the resultant mixture was stirred for 12 hours under reflux. The obtained reaction mixture was diluted with methyl isobutyl ketone, and neutralized with aqueous 1% oxalic acid solution. The obtained mixture was separated to an organic layer and an aqueous layer. The organic layer was washed with water and concentrated. The obtained residue was diluted with propylene glycol methyl ether acetate, and the resultant mixture was concentrated to obtain a polymer having a weight-average molecular weight (Mw) of 4,400 (equivalent to polystyrene) and dispersion degree of 1.22. This polymer had Structural unit (a) and Structural unit (b). This is called as Polymer A4.

Molar ratio of the structural units in Polymer A4 was measured with ¹H-NMR and the result thereof was as followed:

Structural unit (a): Structural unit (b)=49.8:50.2

### COMPARATIVE RESIN SYNTHESIS EXAMPLE 1

Into a flask, 39.7 parts of 2-ethyl-2-adamantyl methacrylate, 103.8 parts of p-acetoxystyrene and 265 parts of isopropanol were charged and the resultant solution was heated to 75° C. under an atmosphere of nitrogen. To the solution, a solution prepared by dissolving 11.05 parts of 2,2′-azobis(2-methylpropionate) in 22.11 parts of isopropanol was added, and the resultant mixture was heated for 12 hours under reflux. The reaction solution was poured into a large amount of methanol. The precipitated polymer, which was a copolymer of 2-ethyl-2-adamantyl methacrylate and p-acetoxystyrene, was isolated by filtration. The isolated polymer was mixed with 10.3 parts of 4-dimethylaminopyridine and 202 parts of methanol, and the resultant mixture was heated for 20 hours under reflux. The reaction solution was cooled and neutralized with 7.6 parts of glacial acetic acid. The obtained mixture was poured into a large amount of water. The precipitated polymer was isolated by filtration and the isolated polymer was dissolved in acetone and the resultant solution was poured into a large amount of water to cause precipitation of the polymer. This isolation-dissolution-precipitation operation was repeated three times. As a result, 95.9 parts of a polymer having a weight-average molecular weight (Mw) of about 8,600 (equivalent to polystyrene) was obtained. This polymer had Structural unit (a) and the structural unit represented by the following formula (c) (hereinafter, simply referred to as Structural unit (c)). This is called as Polymer B1.

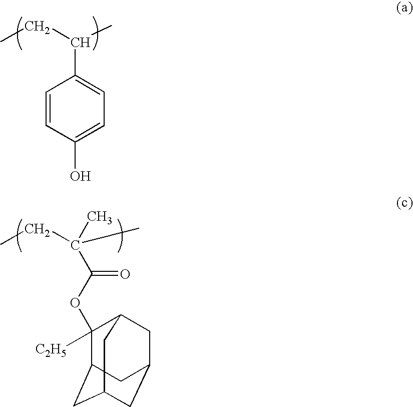

Molar ratio of the structural units in Polymer B1 was measured with ¹³C-NMR and the result thereof was as followed:

Structural unit (a): Structural unit (c)=80:20

### COMPARATIVE RESIN SYNTHESIS EXAMPLE 2

Hundred two point eight parts of a polymer having a weight-average molecular weight (Mw) of about 8,200 (equivalent to polystyrene) was obtained according to the same manner as that of Comparative Resin Synthesis Example 1, except that 59.6 parts of 2-ethyl-2-adamantyl methacrylate was used in place of 39.7 parts of 2-ethyl-2-adamantyl methacrylate, and 90.8 parts of p-acetoxystyrene was used in place of 103.8 parts of p-acetoxystyrene. This polymer had Structural unit (a) and Structural unit (c). This is called as Polymer B2.

Molar ratio of the structural units in Polymer B2 was measured with ¹³C-NMR and the result thereof was as followed:

Structural unit (a): Structural unit (c)=70:30

### EXAMPLES 5 TO 8 AND COMPARATIVE EXAMPLES 1 AND 2

### <Acid Generator>

Acid generator P1:
triphenylsulfonium
4-oxo-1-adanantyloxycarbonyldifluoromethanesulfonate

Acid generator P2:
triphenylsulfonium 2,4,6-triisopropylbenzenesulfonate

Acid generator P3:
N-(n-butylsulfonyloxy)succinimide

### <Resin>

Polymer A1

Polymer A2

Polymer A3

Polymer A4

Polymer B1

Polymer B2

### <Quencher>

Q1: 2,6-diisopropylaniline

Q2: tetrabutylammonium hydroxide

### <Solvent>

| | | |
|---|---|---|
| Y1: | propylene glycol monomethyl ether acetate | 450 parts |
| | propylene glycol monomethyl ether | 40 parts |
| | γ-butyrolactone | 5 parts |
| Y2: | propylene glycol monomethyl ether acetate | 420 parts |
| | propylene glycol monomethyl ether | 60 parts |

The following components were mixed and dissolved, further, filtrated through a fluorine resin filter having pore diameter of 0.2 μm, to prepare resist liquid.

Resin (kind and amount are described in Table 1)

Acid generator (kind and amount are described in Table 1)

Quencher (kind and amount are described in Table 1)

Solvent (kind is described in Table 1)

TABLE 1

| | | Acid | | |
|---|---|---|---|---|
| | Polymer | generator | Quencher | |
| Ex. | (kind/amount | (kind/amount | (kind/amount | |
| No. | (part)) | (part)) | (part)) | Solvent |
| Ex. 5 | A1/10 | P1/1.5 | Q1/0.075 | Y1 |
| | | | Q2/0.005 | |
| Ex. 6 | A2/10 | P1/1.5 | Q1/0.075 | Y1 |
| | | | Q2/0.005 | |
| Ex. 7 | A3/10 | P1/1.5 | Q1/0.075 | Y1 |
| | | | Q2/0.005 | |
| Ex. 8 | A4/10 | P1/1.5 | Q1/0.075 | Y1 |
| | | | Q2/0.005 | |
| Comp. | B1/5 | P2/1.0 | Q1/0.055 | Y2 |
| Ex. 1 | B2/5 | P3/1.0 | | |
| Comp. | B1/5 | P1/1.5 | Q1/0.075 | Y1 |
| Ex. 2 | B2/5 | | Q2/0.005 | |

Silicon wafers were each contacted with hexamethyldisilazane at 90° C. for 60 seconds on a direct hotplate. Each of the resist compositions prepared as above was spin-coated over the wafers so that the thickness of the resulting film became 0.06 μm after drying. The silicon wafers thus coated with the respective resist compositions were each prebaked on a direct hotplate at a temperature shown in column of “PB” of Table 2 for 60 seconds. Using a writing electron beam lithography system (“HL-800D” manufactured by Hitachi, Ltd., 50 KeV), each wafer on which the respective resist film had been thus formed was exposed to a line and space pattern, while changing stepwise the exposure quantity.

After the exposure, each wafer was subjected to post-exposure baking on a hotplate at a temperature shown in column of “PEB” of Table 2 for 60 seconds and then to paddle development for 60 seconds with an aqueous solution of 2.38 wt % tetramethylammonium hydroxide.

Each of a resist pattern developed on the organic anti-reflective coating substrate after the development was observed with a scanning electron microscope, the results of which are shown in Table 2.

Effective Sensitivity (ES): It was expressed as the amount of exposure that the line pattern and the space pattern become 1:1 after exposure through 0.08 μm line and space pattern mask and development.

Resolution: It is expressed as the minimum size of space pattern which gave the space pattern split by the line pattern at the exposure amount of the effective sensitivity.

Pattern Profile: The resist patterns after conducting a lithography process were observed by a scanning electron microscope. When the cross-section shape of the pattern is rectangle, the pattern profile is good and its evaluation is marked by “O”, when the upper of the pattern was melted and the pattern became smaller, the pattern profile is bad and its evaluation is marked by “X” and when the upper of the pattern was melted, the pattern became smaller, the cross-section shape of the pattern is taper shape and an angle of the side wall of the patter was 70° or less, the pattern profile is very bad and its evaluation is marked by “X X”.

TABLE 2

| | | | | Resolution | Pattern |
|---|---|---|---|---|---|
| Ex. No. | PB (° C.) | PEB (° C.) | ES (μC) | (nm) | Profile |
| Ex. 5 | 110 | 100 | 36 | 50 | ◯ |
| Ex. 6 | 100 | 100 | 32 | 60 | ◯ |
| Ex. 7 | 100 | 100 | 18 | 50 | ◯ |
| Ex. 8 | 100 | 100 | 36 | 70 | ◯ |
| Comp. | 125 | 110 | 10 | 70 | X |
| Ex. 1 | | | | | |
| Comp. | 100 | 100 | 20 | 90 | XX |
| Ex. 2 | | | | | |

The present polymer is a novel polymer and a resist composition comprising the same provides good resist pattern in sensitivity, resolution and pattern profile, and is especially suitable for extreme ultraviolet (EUV) lithography, X-ray lithography and electron beam lithography.

What is claimed is:

1. A polymer comprising a structural unit represented by the formula (I): 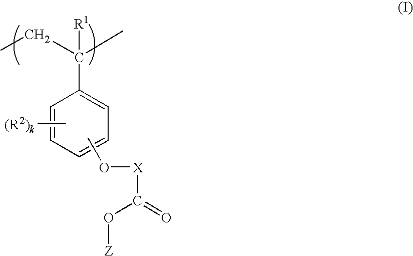
wherein R¹ represents a hydrogen atom or a methyl group, R² is independently in each occurrence a linear or branched chain C1-C6 alkyl group, k represents an integer of 0 to 4, X represents a linear or branched chain C1-C6 alkylene group, Z represents a 2-adamantyl group which may have one or more substituents selected from the group consisting of a linear chain C1-C6 alkyl group, a branched chain C3-C6 alkyl group and a hydroxyl group, and in which a methylene group may be replaced by a carbonyl group, and a structural unit represented by the formula (II): 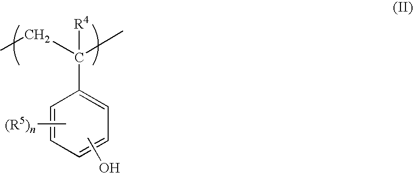
wherein R⁴ represents a hydrogen atom or a methyl group, R⁵ is independently in each occurrence a linear or branched chain C1-C6 alkyl group and n represents an integer of 0 to 4.

2. A resist composition comprising the polymer according to claim 1 and an acid generator.

3. The resist composition according to claim 2, wherein the acid generator is a salt represented by the formula (V): 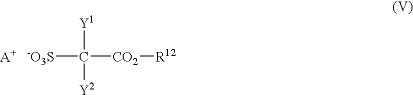
wherein A⁺ represents an organic counter ion, Y¹ and Y² each independently represent a fluorine atom or a C1-C6 perfluoroalkyl group, R¹² represents a C1-C30 hydrocarbon group which may have one or more substituents selected from the group consisting of a C1-C6 alkoxy group, a C1-C4 perfluoroalkyl group, a C1-C6 hydroxyalkyl group, a hydroxyl group and a cyano group, and in which one or more —CH₂— may be replace by —CO— or —O—.
